(19) United States
(12) Patent Application Publication
(10) Pub. No.: US 2024/0347597 A1
(43) Pub. Date: Oct. 17, 2024

(54) SEMICONDUCTOR DEVICE

(71) Applicant: Samsung Electronics Co., Ltd., Suwon-si (KR)

(72) Inventors: JINWOO LEE, Suwon-si (KR); YOUNGKYOU SHIN, Suwon-si (KR); SUTAE KIM, Suwon-si (KR)

(21) Appl. No.: 18/517,893

(22) Filed: Nov. 22, 2023

(30) Foreign Application Priority Data
Apr. 17, 2023 (KR) 10-2023-0050303

(51) Int. Cl. H01L 29/06; H01L 29/417; H01L 29/423; H01L 29/775; H01L 29/786

(52) U.S. Cl. CPC H01L 29/0673; H01L 29/41733; H01L 29/42392; H01L 29/775; H01L 29/78696

(57) ABSTRACT

A semiconductor device includes a substrate including an active pattern, a first semiconductor pattern on the active pattern, and gate electrodes extending in a first direction and arranged in a second direction intersecting the first direction. A first top surface of the first semiconductor pattern includes first and second corners spaced apart from each other in the first direction. The first top surface of the first semiconductor pattern includes a first portion connecting the first and second corners. A length of the first portion of the first semiconductor pattern is greater than a distance in the first direction between the first corner and the second corner.

### CROSS-REFERENCE TO RELATED APPLICATIONS

This U.S. non-provisional patent application claims priority under 35 U.S.C. § 119 to Korean Patent Application No. 10-2023-0050303, filed on Apr. 17, 2023, in the Korean Intellectual Property Office, the entire contents of which are hereby incorporated by reference.

### BACKGROUND OF THE INVENTION

The present disclosure relates to a semiconductor device, and more particularly, to a semiconductor device including a field effect transistor and a method of manufacturing the same.

Semiconductor devices may include integrated circuits including metal-oxide-semiconductor field effect transistors (MOSFETs). As sizes and design rules of semiconductor devices have been reduced, MOSFETs have been scaled down. Operating characteristics of semiconductor devices may be deteriorated by reduction in size of MOSFETs. Accordingly, various methods for forming semiconductor devices which have excellent performance while overcoming limitations caused by high integration have been studied.

### SUMMARY

Embodiments of the inventive concepts provide a semiconductor device capable of improving reliability and electrical characteristics.

Embodiments of the inventive concepts also provide a semiconductor device capable of improving efficiency of processes.

In an aspect, a semiconductor device includes a substrate including an active pattern; a first semiconductor pattern on the active pattern; a source/drain pattern connected to the first semiconductor pattern; and gate electrodes extending in a first direction and arranged in a second direction intersecting the first direction. A first top surface of the first semiconductor pattern may end at a first corner and a second corner, which are spaced apart from each other in the first direction. The first top surface of the first semiconductor pattern may include a first portion connecting the first corner and the second corner. A length of the first portion of the first semiconductor pattern along a direction parallel to the first direction when viewed from a plan view may be greater than a distance in the first direction between the first corner and the second corner.

In an aspect, a semiconductor device includes a substrate including an active pattern; a first semiconductor pattern on the active pattern; a source/drain pattern connected to the first semiconductor pattern; and gate electrodes extending in a first direction and arranged in a second direction intersecting the first direction. A top surface of the active pattern includes a curved surface.

In an aspect, a semiconductor device includes a substrate including an active region; a device isolation layer defining an active pattern on the active region; a first semiconductor pattern and a second semiconductor pattern sequentially stacked on the active pattern, the first and second semiconductor patterns vertically spaced apart from each other; a source/drain pattern connected to the first and second semiconductor patterns; gate electrodes extending in a first direction and arranged in a second direction intersecting the first direction; a gate capping pattern on a top surface of each gate electrode; an interlayer insulating layer on each gate capping pattern; an active contact penetrating the interlayer insulating layer so as to be electrically connected to the source/drain pattern; respective gate contacts penetrating the interlayer insulating layer and the gate capping pattern so as to be electrically connected to a respective gate electrode; a first metal layer including a power interconnection line and first interconnection lines on the interlayer insulating layer, the active contact electrically connected to a corresponding one of the power and first interconnection lines, and the gate contact electrically connected to a corresponding one of the power and first interconnection lines; and a second metal layer on the first metal layer. The second metal layer may include second interconnection lines electrically connected to the first metal layer. A first top surface of the first semiconductor pattern may include a first edge and a second edge, which are spaced apart from each other in the first direction. The first top surface of the first semiconductor pattern may include a first portion connecting the first edge and the second edge. A second top surface of the second semiconductor pattern may include a third edge and a fourth edge, which are spaced apart from each other in the first direction. The second top surface of the second semiconductor pattern may include a second portion connecting the third edge and the fourth edge. A length of the first portion of the first semiconductor pattern along a direction parallel to the first direction when viewed from a plan view may be greater than a distance in the first direction between the first edge and the second edge.

### BRIEF DESCRIPTION OF THE DRAWINGS

FIGS. 1 to 3 are conceptual views illustrating logic cells of semiconductor devices according to some embodiments of the inventive concepts.

FIG. 4 is a plan view illustrating a semiconductor device according to some embodiments of the inventive concepts.

FIGS. 5A, 5B, 5C and 5D are cross-sectional views taken along lines A-A′, B-B′, C-C′ and D-D′ of FIG. 4, respectively.

FIG. 6 is an enlarged view illustrating some embodiments of a region ‘M’ of FIG. 5D.

FIGS. 7A, 7B, 8A, 8B, 9A, 9B, 10A-13A, 10B-13B, and 10C-13C are cross-sectional views illustrating a method of manufacturing a semiconductor device according to some embodiments of the inventive concepts.

### DETAILED DESCRIPTION

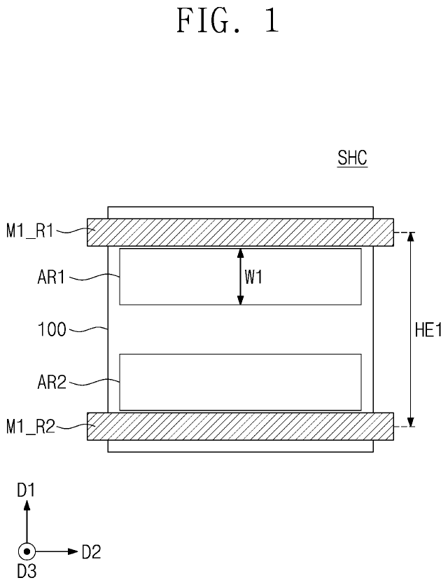

FIGS. 1 to 3 are conceptual views illustrating logic cells of semiconductor devices according to some embodiments of the inventive concepts.

Referring to FIG. 1, a single height cell SHC may be provided. More particularly, a first power interconnection line M1_R1 and a second power interconnection line M1_R2 may be provided on a substrate 100. The first power interconnection line M1_R1 may be a path through which a source voltage (VSS, e.g., a ground voltage) is provided. The second power interconnection line M1_R2 may be a path through which a drain voltage (VDD, e.g., a power voltage) is provided.

The single height cell SHC may be defined between the first power interconnection line M1_R1 and the second power interconnection line M1_R2. The single height cell SHC may include a first active region AR1 and a second active region AR2. One of the first and second active regions AR1 and AR2 may be a PMOSFET region, and the other of the first and second active regions AR1 and AR2 may be an NMOSFET region. Accordingly, the single height cell SHC may have a CMOS structure provided between the first power interconnection line M1_R1 and the second power interconnection line M1_R2.

Each of the first and second active regions AR1 and AR2 may have a first width W1 in a first direction D1. A length of the single height cell SHC in the first direction D1 may be defined as a first height HE1. The first height HE1 may be substantially equal to a distance (e.g., a pitch) between the first power interconnection line M1_R1 and the second power interconnection line M1_R2.

The single height cell SHC may form a logic cell. In the present specification, the logic cell may mean a logic element (e.g., an AND element, an OR element, an XOR element, an XNOR element, an inverter, etc.) for performing a specific function. The logic cell may include transistors and interconnection lines connecting the transistors to each other, which constitute the logic element.

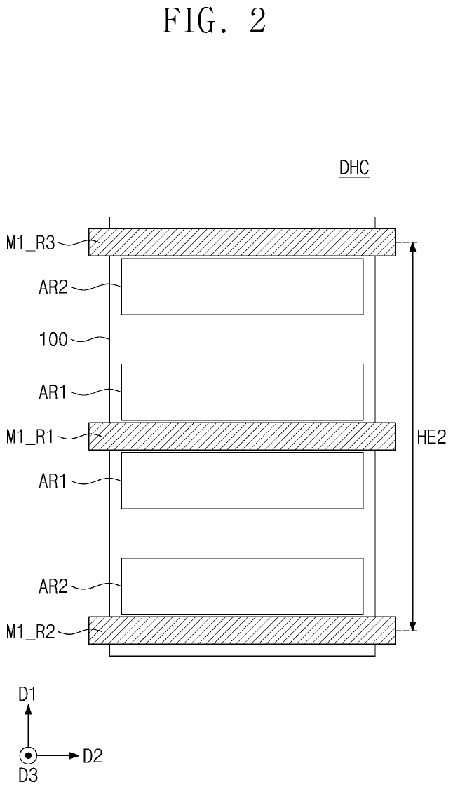

Referring to FIG. 2, a double height cell DHC may be provided. More particularly, a first power interconnection line M1_R1, a second power interconnection line M1_R2 and a third power interconnection line M1_R3 may be provided on a substrate 100. The first power interconnection line M1_R1 may be disposed between the second power interconnection line M1_R2 and the third power interconnection line M1_R3. The third power interconnection line M1_R3 may be a path through which a source voltage (VSS) is provided.

The double height cell DHC may be defined between the second power interconnection line M1_R2 and the third power interconnection line M1_R3. The double height cell DHC may include two first active regions AR1 and two second active regions AR2.

One of the two second active regions AR2 may be adjacent to the second power interconnection line M1_R2. The other of the two second active regions AR2 may be adjacent to the third power interconnection line M1_R3. The two first active regions AR1 may be adjacent to the first power interconnection line M1_R1. The first power interconnection line M1_R1 may be disposed between the two first active regions AR1 when viewed in a plan view.

A length of the double height cell DHC in the first direction D1 may be defined as a second height HE2. The second height HE2 may be about twice the first height HE1 of FIG. 1. The two first active regions AR1 of the double height cell DHC may be combined with each other to operate as a single active region.

In the inventive concepts, the double height cell DHC shown in FIG. 2 may be defined as a multi-height cell. Even though not shown in the drawings, the multi-height cell may include a triple height cell of which a cell height is about three times that of the single height cell SHC.

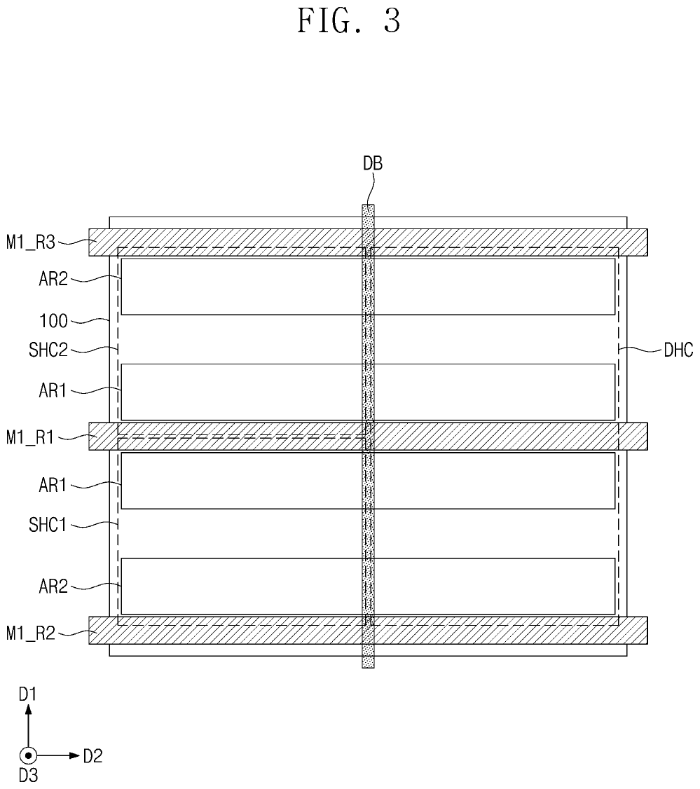

Referring to FIG. 3, a first single height cell SHC1, a second single height cell SHC2 and a double height cell DHC may be two-dimensionally disposed on a substrate 100. The first single height cell SHC1 may be disposed between the first and second power interconnection lines M1_R1 and M1_R2. The second single height cell SHC2 may be disposed between the first and third power interconnection lines M1_R1 and M1_R3. The second single height cell SHC2 may be adjacent to the first single height cell SHC1 in the first direction D1.

The double height cell DHC may be disposed between the second and third power interconnection lines M1_R2 and M1_R3. The double height cell DHC may be adjacent to the first and second single height cells SHC1 and SHC2 in a second direction D2.

An isolation structure DB, also described as a separation structure, may be provided between the first single height cell SHC1 and the double height cell DHC and between the second single height cell SHC2 and the double height cell DHC. An active region of the double height cell DHC may be electrically isolated from an active region of each of the first and second single height cells SHC1 and SHC2 by the isolation structure DB. It should be noted that a “height” as described above (e.g., in connection with a single height cell and double height cell) does not refer to a vertical height in a direction perpendicular to a surface of a semiconductor substrate, but rather refers to a height in the D1 direction in connection with the orientation of FIGS. 1-3.

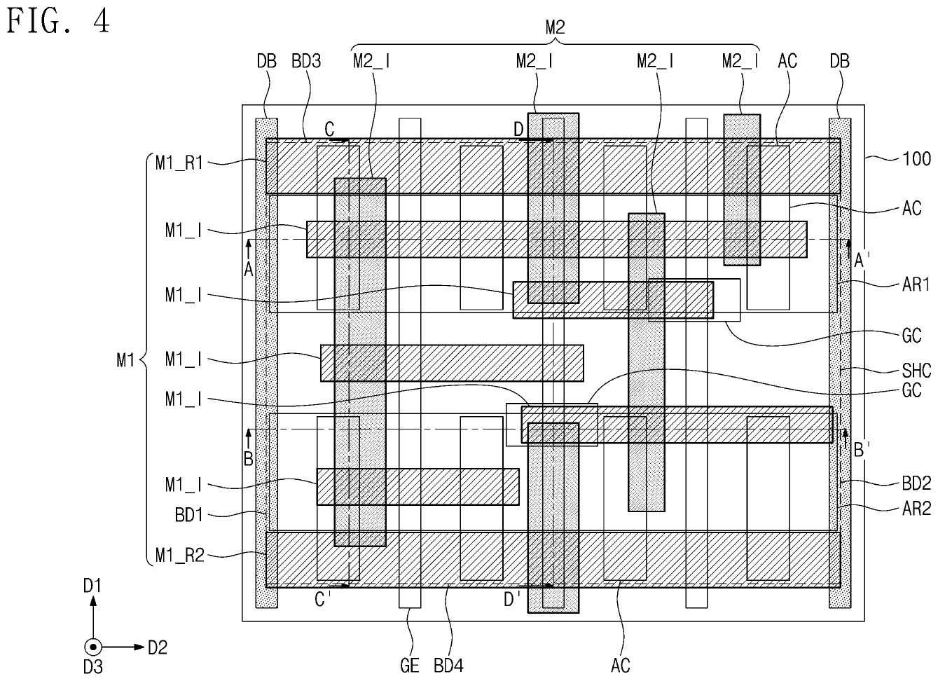

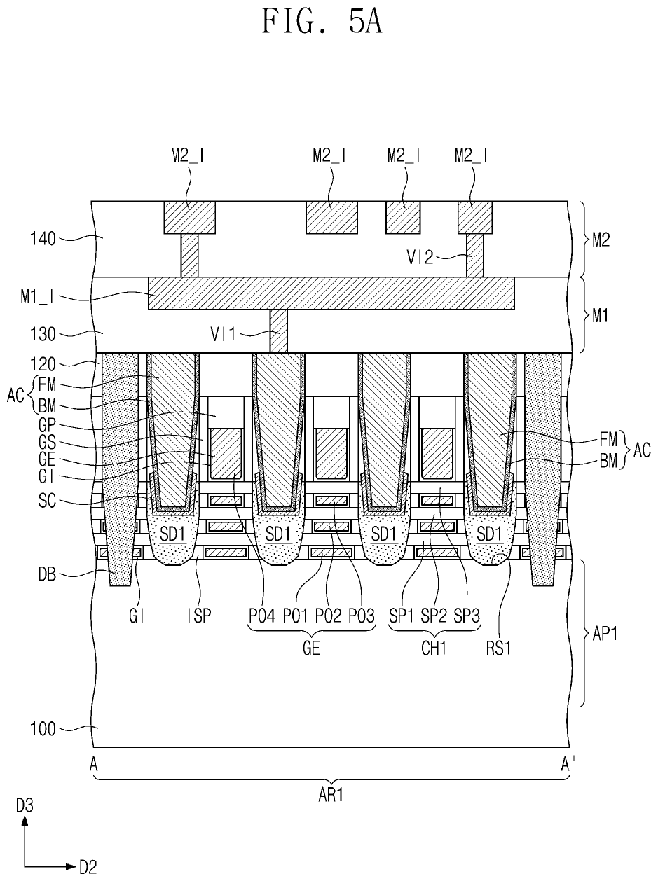

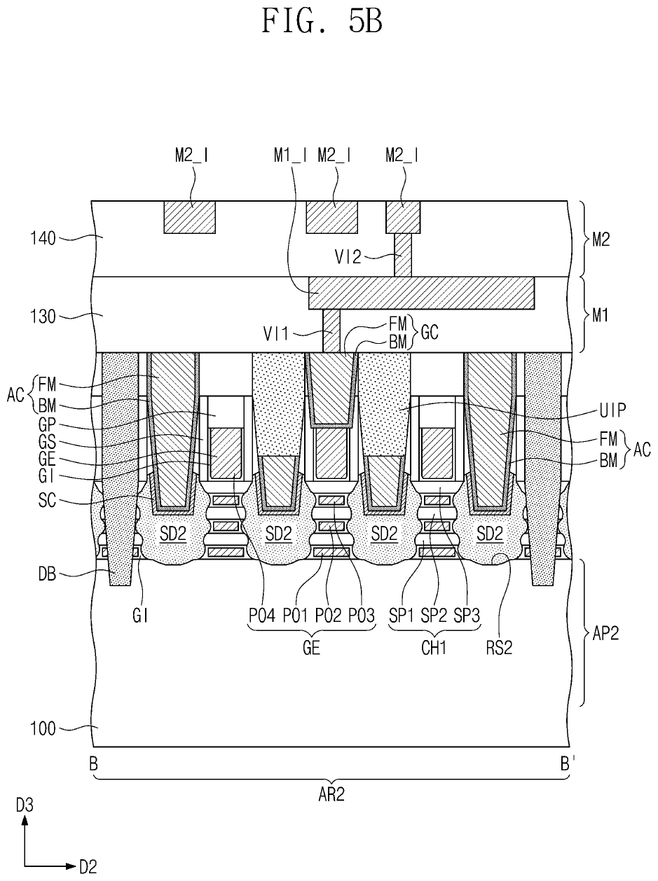

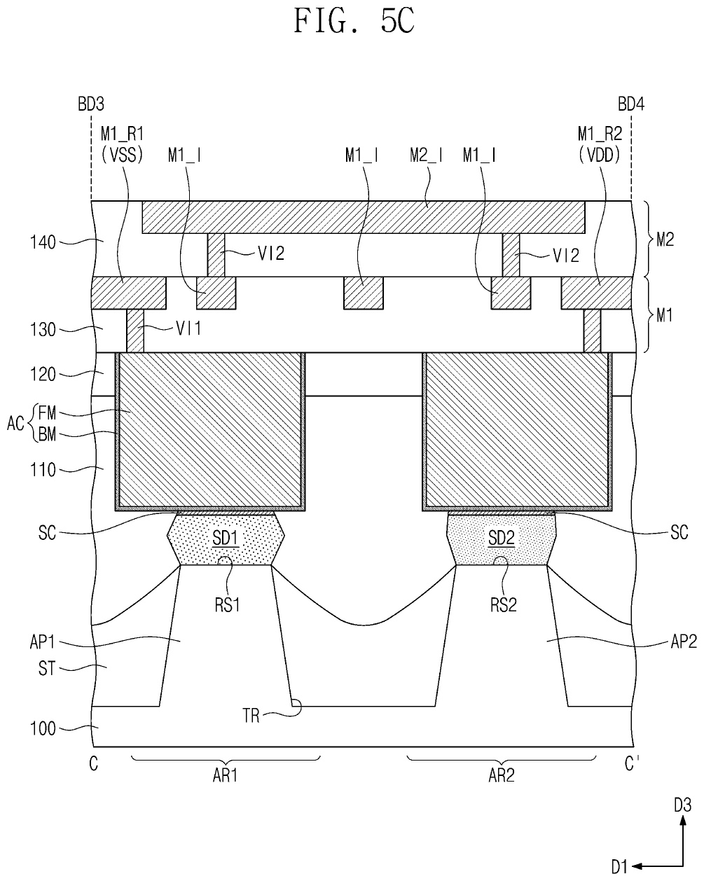

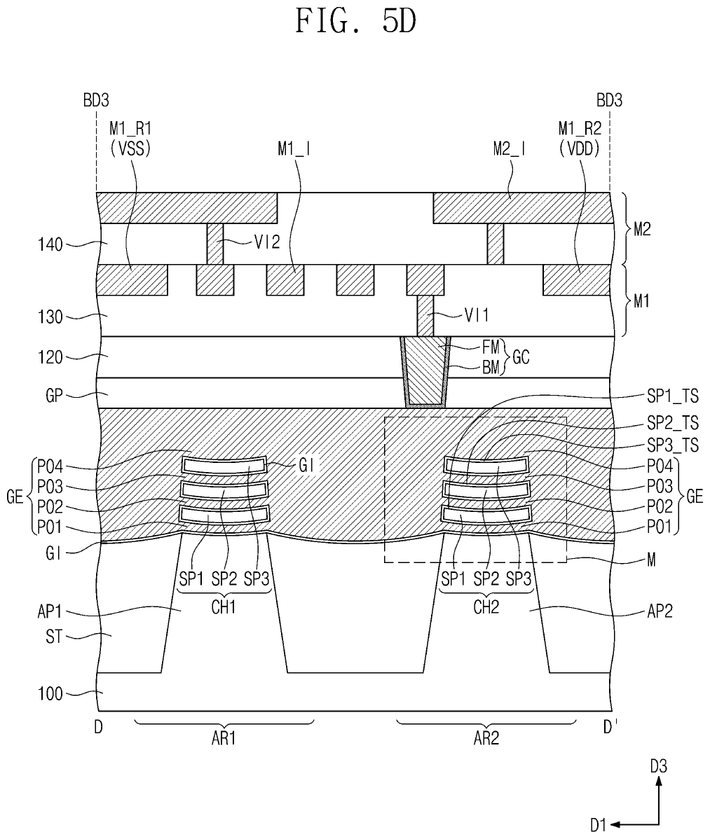

FIG. 4 is a plan view illustrating a semiconductor device according to some embodiments of the inventive concepts. FIGS. 5A, 5B, 5C and 5D are cross-sectional views taken along lines A-A′, B-B′, C-C′ and D-D′ of FIG. 4, respectively. FIGS. 4 and 5A to 5D illustrate more detailed embodiments of the single height cell SHC of FIG. 1.

Referring to FIGS. 4 and 5A to 5D, the single height cell SHC may be provided on the substrate 100. Logic transistors constituting a logic circuit may be disposed on the single height cell SHC. The substrate 100 may be a semiconductor substrate including or formed of silicon, germanium or silicon-germanium, or may be a compound semiconductor substrate. For example, the substrate 100 may be a silicon substrate.

The substrate 100 may include the first active region AR1 and the second active region AR2. Each of the first and second active regions AR1 and AR2 may extend lengthwise in the second direction D2. An item, layer, or portion of an item or layer described as extending “lengthwise” in a particular direction has a length in the particular direction and a width perpendicular to that direction, where the length is greater than the width. In some embodiments, the first active region AR1 may be an NMOSFET region, and the second active region AR2 may be a PMOSFET region.

A first active pattern AP1 and a second active pattern AP2 may be defined by a trench TR formed in an upper portion of the substrate 100. The first active pattern AP1 may be provided on the first active region AR1, and the second active pattern AP2 may be provided on the second active region AR2. The first and second active patterns AP1 and AP2 may extend lengthwise in the second direction D2. The first and second active patterns AP1 and AP2 may be portions of the substrate 100, which vertically protrude above a top surface of the substrate 100.

A device isolation layer ST may be provided on the substrate 100. The device isolation layer ST may fill the trench TR. The device isolation layer ST may include or be a silicon oxide layer or a silicon oxynitride layer. The device isolation layer ST may not cover first and second channel patterns CH1 and CH2 to be described later.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2 and a third semiconductor pattern SP3, which are sequentially stacked. The first to third semiconductor patterns SP1, SP2 and SP3 may be spaced apart from each other in a vertical direction (i.e., a third direction D3).

Each of the first to third semiconductor patterns SP1, SP2 and SP3 may be or may include silicon (Si), germanium (Ge), or silicon-germanium (SiGe). For example, each of the first to third semiconductor patterns SP1, SP2 and SP3 may be crystalline silicon, more particularly, single-crystalline silicon. In some embodiments, the first to third semiconductor patterns SP1, SP2 and SP3 are stacked nanosheets.

Each of the first to third semiconductor patterns SP1, SP2 and SP3 may include first to third top surfaces SP1_TS, SP2_TS and SP3_TS, respectively.

A plurality of first source/drain patterns SD1 may be provided on the first active pattern AP1. A plurality of first recesses RS1 may be formed on the first active pattern AP1. The first source/drain patterns SD1 may be provided in the first recesses RS1, respectively. The first source/drain patterns SD1 may be dopant (e.g., impurity) regions having a first conductivity type (e.g., an n-type). The first channel pattern CH1 may be disposed between a pair of the first source/drain patterns SD1. The first to third semiconductor patterns SP1, SP2 and SP3 stacked sequentially may connect the pair of first source/drain patterns SD1 to each other.

A plurality of second source/drain patterns SD2 may be provided on the second active pattern AP2. A plurality of second recesses RS2 may be formed on the second active pattern AP2. The second source/drain patterns SD2 may be provided in the second recesses RS2, respectively. The second source/drain patterns SD2 may be dopant (e.g., impurity) regions having a second conductivity type (e.g., a p-type). The second channel pattern CH2 may be disposed between a pair of the second source/drain patterns SD2. The first to third semiconductor patterns SP1, SP2 and SP3 stacked sequentially may connect the pair of second source/drain patterns SD2 to each other.

The first and second source/drain patterns SD1 and SD2 may be epitaxial patterns formed by a selective epitaxial growth (SEG) process. For some examples, a top surface of each of the first and second source/drain patterns SD1 and SD2 may be higher than the top surface of the third semiconductor pattern SP3. For certain examples, the top surface of at least one of the first and second source/drain patterns SD1 and SD2 may be located at substantially the same level as the top surface of the third semiconductor pattern SP3.

In some embodiments, the first source/drain patterns SD1 may include or be formed of the same semiconductor element (e.g., Si) as the substrate 100. The second source/drain patterns SD2 may include or be formed of a semiconductor element (e.g., SiGe) having a lattice constant greater than a lattice constant of the semiconductor element (e.g., Si) of the substrate 100. Thus, the pair of second source/drain patterns SD2 may provide compressive stress to the second channel pattern CH2 therebetween.

In some embodiments, a sidewall of the second source/drain pattern SD2 may have an uneven embossing shape. In other words, the sidewall of the second source/drain pattern SD2 may have a wave-shaped profile. The sidewall of the second source/drain pattern SD2 may protrude toward first to third portions PO1, PO2 and PO3 of a gate electrode GE to be described later.

Gate electrodes GE may be provided on the first and second channel patterns CH1 and CH2. Each of the gate electrodes GE may intersect the first and second channel patterns CH1 and CH2 and may lengthwise extend in the first direction D1. Each of the gate electrodes GE may vertically overlap with the first and second channel patterns CH1 and CH2. The gate electrodes GE may be arranged in the second direction D2 at a first pitch.

As described above, the gate electrodes GE may extend in the first direction D1 and may be arranged in the second direction D2 intersecting the first direction D1.

The gate electrode GE may include a first portion PO1 disposed between the active pattern AP1 or AP2 and the first semiconductor pattern SP1, a second portion PO2 disposed between the first semiconductor pattern SP1 and the second semiconductor pattern SP2, a third portion PO3 disposed between the second semiconductor pattern SP2 and the third semiconductor pattern SP3, and a fourth portion PO4 on the third semiconductor pattern SP3.

The gate electrode GE may be provided on the top surface, a bottom surface and both sidewalls of each of the first to third semiconductor patterns SP1, SP2 and SP3. In other words, the transistor according to the present embodiments may be a three-dimensional field effect transistor (e.g., a MBCFET or a GAAFET) in which the gate electrode GE three-dimensionally surrounds a channel.

On the first active region AR1, an inner spacer ISP may be disposed between the first source/drain pattern SD1 and each of the first to third portions PO1, PO2 and PO3 of the gate electrode GE. Each of the first to third portions PO1, PO2 and PO3 of the gate electrode GE may be spaced apart from the first source/drain pattern SD1 with the inner spacer ISP interposed therebetween. The inner spacer ISP may prevent a leakage current from the gate electrode GE.

Referring again to FIGS. 4 and 5A to 5D, a pair of gate spacers GS may be disposed on both (e.g., opposite) sidewalls of the fourth portion PO4 of the gate electrode GE, respectively. The gate spacers GS may extend along the gate electrode GE in the first direction D1. Top surfaces of the gate spacers GS may be higher than a top surface of the gate electrode GE. The top surfaces of the gate spacers GS may be coplanar with a top surface of a first interlayer insulating layer 110 to be described later. For some examples, the gate spacers GS may include or be formed of at least one of SiCN, SiCON, or SiN. For certain examples, each of the gate spacers GS may include or be formed of a multi-layer formed of at least two of SiCN, SiCON, or SiN. In some embodiments, the gate spacer GS may include a Si-containing insulating material. The gate spacer GS may function as an etch stop layer in a process of forming active contacts AC to be described later. The active contacts AC may be formed to be self-aligned by the gate spacer GS.

Referring again to FIGS. 4 and 5A to 5D, a gate capping pattern GP may be provided on each gate electrode GE. The gate capping pattern GP may extend along the gate electrode GE in the first direction D1. The gate capping pattern GP may include a material having an etch selectivity with respect to first and second interlayer insulating layers 110 and 120 to be described later. For example, the gate capping pattern GP may include or be formed of at least one of SiON, SiCN, SiCON, or SiN.

A gate insulating layer GI, also described as a gate dielectric layer, may be disposed between the gate electrode GE and the first channel pattern CH1 and between the gate electrode GE and the second channel pattern CH2. The gate insulating layer GI may cover the top surface, the bottom surface and both sidewalls of each of the first to third semiconductor patterns SP1, SP2 and SP3. The gate insulating layer GI may cover a top surface of the device isolation layer ST under the gate electrode GE.

In some embodiments, the gate insulating layer GI may include or be a silicon oxide layer, a silicon oxynitride layer, and/or a high-k dielectric layer. For example, the gate insulating layer GI may have a structure in which the silicon oxide layer and the high-k dielectric layer are stacked. The high-k dielectric layer may include a high-k dielectric material of which a dielectric constant is higher than that of the silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In certain embodiments, the semiconductor device according to the inventive concepts may include a negative capacitance (NC) FET using a negative capacitor. For example, the gate insulating layer GI may include a ferroelectric material layer having ferroelectric properties, and a paraelectric material layer having paraelectric properties.

The ferroelectric material layer may have a negative capacitance, and the paraelectric material layer may have a positive capacitance. For example, when two or more capacitors are connected in series to each other and a capacitance of each of the capacitors has a positive value, a total capacitance may be reduced to be less than the capacitance of each of the capacitors. On the contrary, when at least one of capacitances of two or more capacitors connected in series to each other has a negative value, a total capacitance may have a positive value and may be greater than an absolute value of the capacitance of each of the capacitors.

When the ferroelectric material layer having the negative capacitance is connected in series to the paraelectric material layer having the positive capacitance, a total capacitance value of the ferroelectric and paraelectric material layers connected in series may increase. The transistor including the ferroelectric material layer may have a subthreshold swing (SS) less than 60 mV/decade at room temperature by using the increase in the total capacitance value.

The ferroelectric material layer may have the ferroelectric properties. For example, the ferroelectric material layer may include or may be at least one of hafnium oxide, hafnium zirconium oxide, barium strontium titanium oxide, barium titanium oxide, or lead zirconium titanium oxide. Here, for some examples, the hafnium zirconium oxide may be a material formed by doping hafnium oxide with zirconium (Zr). For certain examples, the hafnium zirconium oxide may be a compound of hafnium (Hf), zirconium (Zr) and oxygen (O).

The ferroelectric material layer may further include dopants doped therein. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A kind of the dopants included in the ferroelectric material layer may be changed depending on a kind of the ferroelectric material included in the ferroelectric material layer.

When the ferroelectric material layer includes hafnium oxide, the dopants included in the ferroelectric material layer may include at least one of, for example, gadolinium (Gd), silicon (Si), zirconium (Zr), aluminum (Al), or yttrium (Y).

When the dopants are aluminum (Al), the ferroelectric material layer may include aluminum of 3 at % (atomic %) to 8 at %. Here, a ratio of the dopants may be a ratio of the amount of aluminum to a sum of the amounts of hafnium and aluminum.

When the dopants are silicon (Si), the ferroelectric material layer may include silicon of 2 at % to 10 at %. When the dopants are yttrium (Y), the ferroelectric material layer may include yttrium of 2 at % to 10 at %. When the dopants are gadolinium (Gd), the ferroelectric material layer may include gadolinium of 1 at % to 7 at %. When the dopants are zirconium (Zr), the ferroelectric material layer may include zirconium of 50 at % to 80 at %.

The paraelectric material layer may have the paraelectric properties. For example, the paraelectric material layer may include at least one of silicon oxide or a metal oxide having a high-k dielectric constant. For example, the metal oxide included in the paraelectric material layer may include at least one of, but is not limited to, hafnium oxide, zirconium oxide, or aluminum oxide.

The ferroelectric material layer and the paraelectric material layer may include or be the same material. The ferroelectric material layer may have the ferroelectric properties, but the paraelectric material layer may not have the ferroelectric properties. For example, when the ferroelectric material layer and the paraelectric material layer include hafnium oxide, a crystal structure of hafnium oxide included in the ferroelectric material layer may be different from a crystal structure of hafnium oxide included in the paraelectric material layer.

The ferroelectric material layer may have a thickness showing the ferroelectric properties. For example, the thickness of the ferroelectric material layer may be in a range from 0.5 nm to 10 nm, but embodiments of the inventive concepts are not limited thereto. A critical thickness showing the ferroelectric properties may be changed depending on a kind of a ferroelectric material, and thus the thickness of the ferroelectric material layer may be changed depending on a kind of the ferroelectric material included therein.

For some examples, the gate insulating layer GI may include a single ferroelectric material layer. For certain examples, the gate insulating layer GI may include a plurality of the ferroelectric material layers spaced apart from each other. The gate insulating layer GI may have a stack structure in which the ferroelectric material layers and the paraelectric material layers are alternately stacked.

Referring again to FIGS. 4 and 5A to 5D, the gate electrode GE may include a first metal pattern and a second metal pattern on the first metal pattern. The first metal pattern may be provided on the gate insulating layer GI and may be adjacent to the first to third semiconductor patterns SP1, SP2 and SP3. The first metal pattern may be a work function metal of adjusting a threshold voltage of a transistor. A desired threshold voltage of the transistor may be obtained by adjusting a thickness and a composition of the first metal pattern. For example, the first to third portions PO1, PO2 and PO3 of the gate electrode GE may be formed of the first metal pattern corresponding to the work function metal.

The first metal pattern may include or be a metal nitride layer. For example, the first metal pattern may include nitrogen (N) and at least one metal selected from a group consisting of titanium (Ti), tantalum (Ta), aluminum (Al), tungsten (W), and molybdenum (Mo). In addition, the first metal pattern may further include carbon (C). In some embodiments, the first metal pattern may include a plurality of stacked work function metal layers.

The second metal pattern may include or be a metal having a resistance lower than that of the first metal pattern. For example, the second metal pattern may include or be at least one metal selected from a group consisting of tungsten (W), aluminum (Al), titanium (Ti), and tantalum (Ta). For example, the fourth portion PO4 of the gate electrode GE may include the first metal pattern and the second metal pattern on the first metal pattern.

A first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with the top surface of the gate capping pattern GP and the top surface of the gate spacer GS. A second interlayer insulating layer 120 covering the gate capping pattern GP may be disposed on the first interlayer insulating layer 110. A third interlayer insulating layer 130 may be provided on the second interlayer insulating layer 120. A fourth interlayer insulating layer 140 may be provided on the third interlayer insulating layer 130. For example, each of the first to fourth interlayer insulating layers 110 to 140 may include or be a silicon oxide layer.

The single height cell SHC may have a first boundary BD1 and a second boundary BD2, which are opposite to each other in the second direction D2. The first and second boundaries BD1 and BD2 may extend in the first direction D1. The single height cell SHC may have a third boundary BD3 and a fourth boundary BD4, which are opposite to each other in the first direction D1. The third and fourth boundaries BD3 and BD4 may extend in the second direction D2.

A pair of isolation structures DB opposite to each other in the second direction D2 may be provided at both sides of the single height cell SHC, respectively. For example, the pair of isolation structures DB may be provided on the first and second boundaries BD1 and BD2 of the single height cell SHC, respectively. The isolation structure DB may extend in the first direction D1 in parallel to the gate electrode GE. A pitch between the isolation structure DB and the gate electrode GE adjacent thereto may be equal to the first pitch.

The isolation structure DB may penetrate the first and second interlayer insulating layers 110 and 120 and may extend into the first and second active patterns AP1 and AP2. The isolation structure DB may penetrate an upper portion of each of the first and second active patterns AP1 and AP2. The isolation structure DB may electrically isolate the active region of the single height cell SHC from an active region of another cell adjacent thereto.

Active contacts AC may penetrate the first and second interlayer insulating layers 110 and 120 so as to be electrically connected to the first and second source/drain patterns SD1 and SD2. A pair of the active contacts AC may be provided at both sides (e.g., opposite sides) of the gate electrode GE, respectively. The active contact AC may have a bar shape extending in the first direction D1 when viewed in a plan view.

The active contact AC may be a self-aligned contact. For example, the active contact AC may be formed to be self-aligned with the gate capping pattern GP and the gate spacer GS. For example, the active contact AC may cover at least a portion of a sidewall of the gate spacer GS. Even though not shown in the drawings, the active contact AC may cover a portion of the top surface of the gate capping pattern GP.

Metal-semiconductor compound layers SC (e.g., silicide layers) may be disposed between the active contact AC and the first source/drain pattern SD1 and between the active contact AC and the second source/drain pattern SD2, respectively. The active contact AC may be electrically connected to the source/drain pattern SD1 or SD2 through the metal-semiconductor compound layer SC. For example, the metal-semiconductor compound layer SC may be or may include at least one of titanium silicide, tantalum silicide, tungsten silicide, nickel silicide, or cobalt silicide.

Gate contacts GC may penetrate the second interlayer insulating layer 120 and the gate capping patterns GP so as to be electrically connected to the gate electrodes GE, respectively. The gate contacts GC may overlap with the first active region AR1 and the second active region AR2, respectively, when viewed in a plan view. For example, the gate contact GC may be provided on the second active pattern AP2 (see FIG. 5B).

In some embodiments, referring to FIG. 5B, a space on the active contact AC adjacent to the gate contact GC may be filled with an upper insulating pattern UIP. A bottom surface of the upper insulating pattern UIP may be lower than a bottom surface of the gate contact GC. For example, a top surface of the active contact AC adjacent to the gate contact GC may be lower than the bottom surface of the gate contact GC due to the upper insulating pattern UIP. Thus, it is possible to prevent an electrical short between the gate contact GC and the active contact AC adjacent thereto.

Each of the active contact AC and the gate contact GC may include a conductive pattern FM and a barrier pattern BM surrounding the conductive pattern FM. For example, the conductive pattern FM may include or be formed of at least one metal of aluminum, copper, tungsten, molybdenum, or cobalt. The barrier pattern BM may cover sidewalls and a bottom surface of the conductive pattern FM. The barrier pattern BM may include or be formed of a metal layer/a metal nitride layer. The metal layer may be or include at least one of titanium, tantalum, tungsten, nickel, cobalt, or platinum. The metal nitride layer may be or include at least one of a titanium nitride (TiN) layer, a tantalum nitride (TaN) layer, a tungsten nitride (WN) layer, a nickel nitride (NiN) layer, a cobalt nitride (CON) layer, or a platinum nitride (PtN) layer.

A first metal layer M1 may be provided in the third interlayer insulating layer 130. For example, the first metal layer M1 may include the first power interconnection line M1_R1, the second power interconnection line M1_R2, and first interconnection lines M1_I. The interconnection lines M1_R1, M1_R2 and M1_I of the first metal layer M1 may extend in the second direction D2 in parallel to each other.

More particularly, the first and second power interconnection lines M1_R1 and M1_R2 may be provided on the third and fourth boundaries BD3 and BD4 of the single height cell SHC, respectively. The first power interconnection line M1_R1 may extend in the second direction D2 along the third boundary BD3. The second power interconnection line M1_R2 may extend in the second direction D2 along the fourth boundary BD4.

The first interconnection lines M1_I (also described as wiring lines) of the first metal layer M1 may be disposed between the first and second power interconnection lines M1_R1 and M1_R2. The first interconnection lines M1_I of the first metal layer M1 may be arranged in the first direction D1 at a second pitch. The second pitch may be less than the first pitch. A line width of each of the first interconnection lines M1_I may be less than a line width of each of the first and second power interconnection lines M1_R1 and M1_R2. The first and second power interconnection lines M1_R1 and M1_R2 may be lines configured to connect to a power source circuit and connected to components that operate by receiving power (e.g., voltage).

The first metal layer M1 may be connected to first vias VI1. The first vias VI1 may be provided under the interconnection lines M1_R1, M1_R2 and M1_I of the first metal layer M1. The active contact AC may be electrically connected to a corresponding interconnection line of the first metal layer M1 through a corresponding one of the first vias VI1. The gate contact GC may be electrically connected to a corresponding interconnection line of the first metal layer M1 through a corresponding one of the first vias VI1.

The interconnection line of the first metal layer M1 and the first via VI1 thereunder may be formed using different processes. For example, each of the interconnection line and the first via VI1 of the first metal layer M1 may be formed using a single damascene process. The semiconductor device according to the present embodiments may be formed using processes for forming components less than 20 nm.

A second metal layer M2 may be provided in the fourth interlayer insulating layer 140. The second metal layer M2 may include a plurality of second interconnection lines M2_I. Each of the second interconnection lines M2_I of the second metal layer M2 may have a line shape or bar shape extending in the first direction D1. For example, the second interconnection lines M2_I may extend in the first direction D1 in parallel to each other.

The second metal layer M2 may be connected to second vias VI2 provided under the second interconnection lines M2_I. The interconnection lines of the first metal layer M1 may be electrically connected to the interconnection lines of the second metal layer M2 through the second vias VI2. For example, the interconnection line of the second metal layer M2 and the second via VI2 thereunder may be formed together by a dual damascene process.

The interconnection lines of the first metal layer M1 and the interconnection lines of the second metal layer M2 may include the same conductive material or different conductive materials. For example, the interconnection lines of the first metal layer M1 and the interconnection lines of the second metal layer M2 may be or may include at least one metal material of aluminum, copper, tungsten, molybdenum, ruthenium, or cobalt. Even though not shown in the drawings, metal layers (e.g., M3, M4, M5, . . . ) stacked on the fourth interlayer insulating layer 140 may be additionally provided. Each of the stacked metal layers may include interconnection lines for routing between cells.

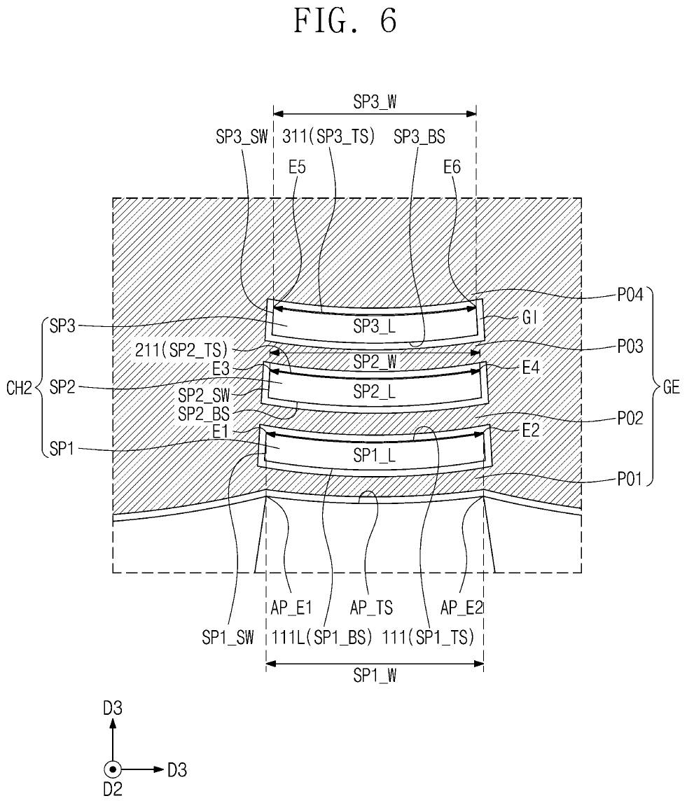

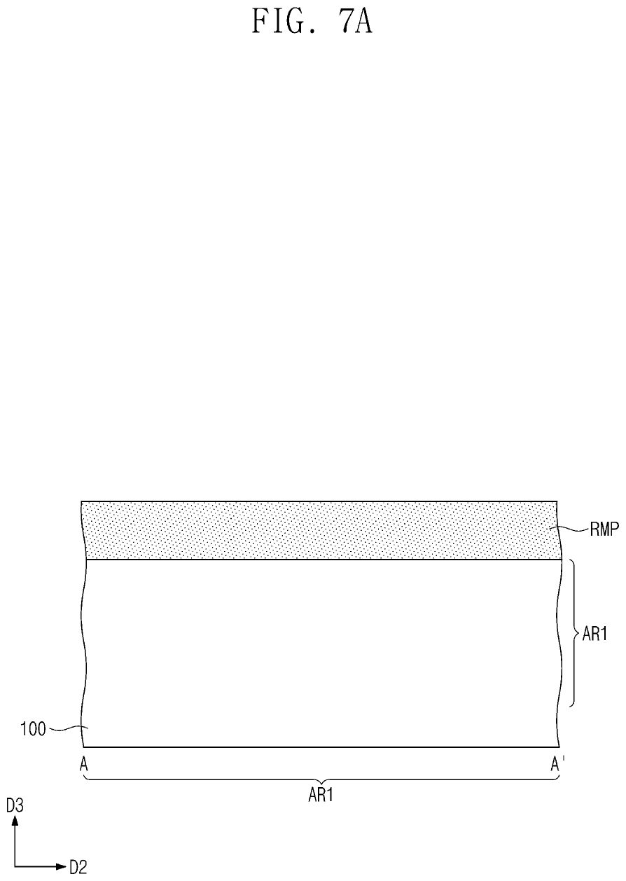

FIG. 6 is an enlarged view illustrating some embodiments of a region ‘M’ of FIG. 5D. The first semiconductor pattern SP1, the second semiconductor pattern SP2 and the third semiconductor pattern SP3 will be described in more detail with reference to FIGS. 5D and 6.

Referring to FIG. 6, the first semiconductor pattern SP1, the second semiconductor pattern SP2 and the third semiconductor pattern SP3 may be spaced apart from each other in the third direction D3 perpendicular to a top surface of the substrate 100. The first semiconductor pattern SP1, the second semiconductor pattern SP2 and the third semiconductor pattern SP3 may have curve shapes.

The gate electrodes GE may extend in the first direction D1 and may be arranged in the second direction D2 intersecting the first direction D1.

The first semiconductor pattern SP1 may include the first top surface SP1_TS. The first semiconductor pattern SP1 may include a first bottom surface SP1_BS. The first semiconductor pattern SP1 may include a first sidewall SP1_SW connecting the first top surface SP1_TS and the first bottom surface SP1_BS and a sidewall opposite the first sidewall SP1_SW and connecting the first top surface SP1_TS and the first bottom surface SP1_BS.

As viewed from the second direction D2, the first top surface SP1_TS may include and may end at a first corner E1 and a second corner E2, which are spaced apart from each other in the first direction D1 and which are formed between the first top surface SP1_TS and the first sidewall SP1_SW and between the first top surface SP1_TS and the sidewall opposite the first sidewall SP1_SW. Therefore, the first corner E1 may be defined as a corner at which the first top surface SP1_TS meets the first sidewall SP1_SW (e.g., at a particular angle). The first corner E1 as viewed from the second direction D2 may correspond to a first edge extending in the second direction D2 and formed where the first top surface SP1_TS meets the first sidewall SP1_SW. The second corner E2 may be defined as a corner at which the first top surface SP1_TS meets the sidewall opposite the first sidewall SP1_SW and which is opposite to the first corner E1 (e.g., at a particular angle). The second corner E1 as viewed from the second direction D2 may correspond to a second edge extending in the second direction D2 and formed where the first top surface SP1_TS meets the sidewall opposite the first sidewall SP1_SW.

The first top surface SP1_TS of the first semiconductor pattern SP1 may include a first portion 111 connecting the first corner E1 and the second corner E2. A cross section of the first portion 111 of the first semiconductor pattern SP1 may be disposed in a plane defined by the first direction D1 and the third direction D3.

A distance in the first direction D1 between the first corner E1 and the second corner E2 may be defined as a first straight width SP1_W.

A length SP1_L of the first portion 111 along a direction parallel to the first direction D1 from a plan view may be greater than the distance in the first direction D1 between the first corner E1 and the second corner E2. Therefore, the length SP1_L of the first portion 111 may be greater than the first straight width SP1_W, for example due to the curvature of the first portion 111.

A top surface of the active pattern AP1 or AP2, which overlaps the first top surface SP1_TS of the first semiconductor pattern SP1 in the third direction D3, may be defined as an active curved surface AP_TS. The active curved surface AP_TS may include and may end at a first active corner AP_E1 and a second active corner AP_E2, which are spaced apart from each other in the first direction D1.

The active curved surface AP_TS of the active pattern AP1 or AP2 may include an active curved portion connecting the first active corner AP_E1 and the second active corner AP_E2. The active curved portion may overlap the first portion 111 in the third direction D3. The active curved portion may be curved from the first active corner AP_E1 (which may correspond to an edge of the active pattern between a top surface and a side surface) to the second active corner AP_E2. For example, two side sections adjacent to respective edges of the active pattern and a central section between the two side sections may all have a curved surface. The same curved arrangement may apply to the other curved surfaces described above and below.

The active curved surface AP_TS may be or include a curved surface. The first top surface SP1_TS may be or include a curved surface. The first bottom surface SP1_BS may be or include a curved surface.

A curvature of the curved surface of the first top surface SP1_TS may be equal to a curvature of the curved surface of the first bottom surface SP1_BS. The curvature of the curved surface of the first top surface SP1_TS may be equal to a curvature of the curved surface of the active curved surface AP_TS. A curvature of the first portion 111 may be equal to a curvature of the active curved portion. For example, because each layer is conformally formed on the adjacent lower layer (as described in greater detail below), these curvatures of the different layers may be the same. The curvature may refer, for example, to a radius of curvature, or to a profile shape of the curve that forms the various surfaces or portions.

The first bottom surface SP1_BS of the first semiconductor pattern SP1 may include and may end at a first lower corner LE1 and a second lower corner LE2, which are spaced apart from each other in the first direction D1. The first lower corner LE1 may be defined as a corner at which the first bottom surface SP1_BS meets the first sidewall SP1_SW. The second lower corner LE2 may be defined as a corner at which the first bottom surface SP1_BS meets the sidewall opposite the first sidewall SP1_SW and which is opposite to the first lower corner LE1.

The first bottom surface SP1_BS of the first semiconductor pattern SP1 may include a first lower portion 111L connecting the first lower corner LE1 and the second lower corner LE2. A cross section of the first lower portion 111L of the first semiconductor pattern SP1 may be disposed in the plane defined by the first direction D1 and the third direction D3.

The second semiconductor pattern SP2 may be spaced apart from the first semiconductor pattern SP1 in the third direction D3 perpendicular to the top surface of the substrate 100. The second semiconductor pattern SP2 may overlap with the first semiconductor pattern SP1 in the third direction D3 intersecting the first direction D1 and the second direction D2.

The second semiconductor pattern SP2 may be provided above the first semiconductor pattern SP1. The second semiconductor pattern SP2 may include the second top surface SP2_TS. The second semiconductor pattern SP2 may include a second bottom surface SP2_BS. The second semiconductor pattern SP2 may include a second sidewall SP2_SW connecting the second top surface SP2_TS and the second bottom surface SP2_BS and a sidewall opposite the second sidewall SP2_SW and connecting the second top surface SP2_TS and the second bottom surface SP2_BS.

The second top surface SP2_TS may be or include a curved surface. The second bottom surface SP2_BS may be or include a curved surface.

The second top surface SP2_TS may include and may end at a third corner E3 and a fourth corner E4, which are spaced apart from each other in the first direction D1. The third corner E3 may be defined as a corner at which the second top surface SP2_TS meets the second sidewall SP2_SW. The fourth corner E4 may be defined as a corner at which the second top surface SP2_TS meets the sidewall opposite the second sidewall SP2_SW and which is opposite to the third corner E3.

The second top surface SP2_TS of the second semiconductor pattern SP2 may include a second portion 211 connecting the third corner E3 and the fourth corner E4. A cross section of the second portion 211 of the second semiconductor pattern SP2 may be disposed in the plane defined by the first direction D1 and the third direction D3.

A distance in the first direction D1 between the third corner E3 and the fourth corner E4 may be defined as a second straight width SP2_W.

A length SP2_L of the second portion 211 may be greater than the distance in the first direction D1 between the third corner E3 and the fourth corner E4. In other words, the length SP2_L of the second portion 211 may be greater than the second straight width SP2_W.

A curvature of the curved surface of the second top surface SP2_TS may be equal to a curvature of the curved surface of the second bottom surface SP2_BS. The curvature of the curved surface of the second top surface SP2_TS may be equal to the curvature of the active curved surface AP_TS. A curvature of the second portion 211 may be equal to the curvature of the active curved portion.

The third semiconductor pattern SP3 may be provided above the second semiconductor pattern SP2. The third semiconductor pattern SP3 may overlap with the second semiconductor pattern SP2 in the third direction D3. The second semiconductor pattern SP2 and the third semiconductor pattern SP3 may be spaced apart from each other in the third direction D3.

The third semiconductor pattern SP3 may include the third top surface SP3_TS. The third semiconductor pattern SP3 may include a third bottom surface SP3_BS. The third semiconductor pattern SP3 may include a third sidewall SP3_SW connecting the third top surface SP3_TS and the third bottom surface SP3_BS and a sidewall opposite the third sidewall SP3_SW and connecting the third top surface SP3_TS and the third bottom surface SP3_BS.

The third top surface SP3_TS may be or include a curved surface. The third bottom surface SP3_BS may be or include a curved surface.

The third top surface SP3_TS may include and may end at a fifth corner E5 and a sixth corner E6, which are spaced apart from each other in the first direction D1. The fifth corner E5 may be defined as a corner at which the third top surface SP3_TS meets the third sidewall SP3_SW. The sixth corner E6 may be defined as a corner at which the third top surface SP3_TS meets the sidewall opposite the third sidewall SP3_SW and which is opposite to the fifth corner E5.

The third top surface SP3_TS of the third semiconductor pattern SP3 may include a third portion 311 connecting the fifth corner E5 and the sixth corner E6. A cross section of the third portion 311 of the third semiconductor pattern SP3 may be disposed in the plane defined by the first direction D1 and the third direction D3.

A distance in the first direction D1 between the fifth corner E5 and the sixth corner E6 may be defined as a third straight width SP3_W.

A length SP3_L of the third portion 311 may be greater than the distance in the first direction D1 between the fifth corner E5 and the sixth corner E6. In other words, the length SP3_L of the third portion 311 may be greater than the third straight width SP3_W.

A curvature of the curved surface of the third top surface SP3_TS may be equal to a curvature of the curved surface of the third bottom surface SP3_BS. The curvature of the curved surface of the third top surface SP3_TS may be equal to the curvature of the active curved surface AP_TS. A curvature of the third portion 311 may be equal to the curvature of the active curved portion.

In some embodiments, a top surface of the gate insulating layer GI in contact with the active curved surface AP_TS may have a curved surface. In some embodiments, surfaces of the gate insulating layer GI in contact with the first top surface SP1_TS and the first bottom surface SP1_BS of the first semiconductor pattern SP1 may have curved surfaces. Likewise, surfaces of the gate insulating layer GI in contact with top and bottom surfaces of the second and third semiconductor patterns SP2 and SP3 may also have curved surfaces. A curvature of the curved surface of the top surface of the gate insulating layer GI may be equal to the curvature of the first portion 111.

The curvature of the first portion 111 of the first semiconductor pattern SP1 may be equal to the curvature of the second portion 211 of the second semiconductor pattern SP2. The curvature of the first portion 111 may be equal to the curvature of the first lower portion 111L. The curvature of the first portion 111 of the first semiconductor pattern SP1 may be equal to the curvature of the third portion 311 of the third semiconductor pattern SP3. The curvature of the first portion 111 of the first semiconductor pattern SP1 may be equal to the curvature of the active curved portion of the active curved surface AP_TS. A curvature of the surface of the gate insulating layer GI in contact with the active curved surface AP_TS may be equal to the curvature of the curved surface of the first top surface SP1_TS. A curvature of the surface of the gate insulating layer GI in contact with the first top surface SP1_TS of the first semiconductor pattern SP1 may be equal to the curvature of the curved surface of the first top surface SP1_TS of the first semiconductor pattern SP1. A curvature of the surface of the gate insulating layer GI in contact with the first bottom surface SP1_BS of the first semiconductor pattern SP1 may be equal to the curvature of the curved surface of the first top surface SP1_TS of the first semiconductor pattern SP1.

The length SP1_L of the first portion 111 of the first semiconductor pattern SP1 may be greater than the length SP2_L of the second portion 211 of the second semiconductor pattern SP2. For example, the length SP1_L of the first portion 111 may be in a range from 1.02 times to 1.05 times the length SP2_L of the second portion 211. The length SP2_L of the second portion 211 of the second semiconductor pattern SP2 may be greater than the length SP3_L of the third portion 311 of the third semiconductor pattern SP3. For example, the length SP2_L of the second portion 211 may be in a range from 1.02 times to 1.05 times the length SP3_L of the third portion 311.

The first straight width SP1_W of the first semiconductor pattern SP1 may be greater than the second straight width SP2_W of the second semiconductor pattern SP2. The second straight width SP2_W of the second semiconductor pattern SP2 may be greater than the third straight width SP3_W of the third semiconductor pattern SP3.

The length SP1_L of the first portion 111 may be in a range from 1.2 times to 1.4 times the first straight width SP1_W. It should be noted that the curvature included in FIG. 6 is not drawn to scale, but instead is drawn to allow for easier depiction of various labels. A curvature that results in this range helps to increase the surface area at an interface between the semiconductor patterns and the gate electrode without being curved too much to a point where electrical characteristics can exhibit unexpected behaviors.

According to the embodiments of the inventive concepts, the lengths SP1_L, SP2_L and SP3_L of the first to third portions 111, 211 and 311 of the first to third semiconductor patterns SP1, SP2 and SP3 may be greater than the straight widths SP1_W, SP2_W and SP3_W of the first to third semiconductor patterns SP1, SP2 and SP3, respectively, and thus a Fmax value of showing a flowing current per unit area may be increased.

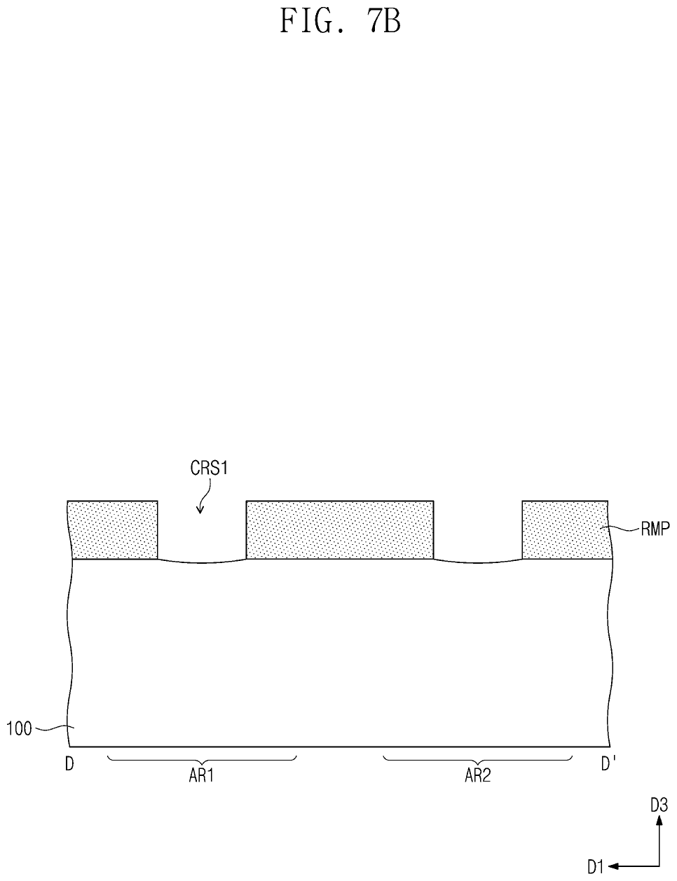

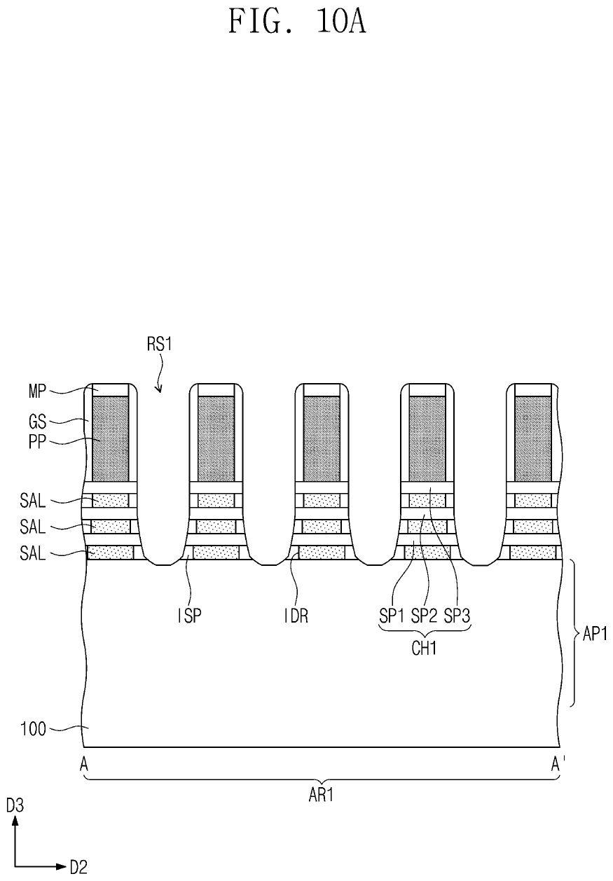

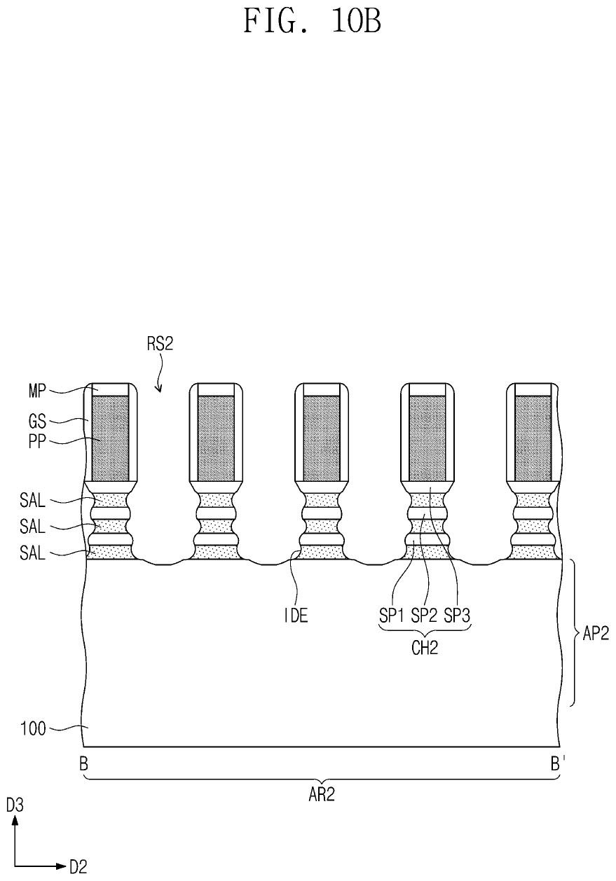

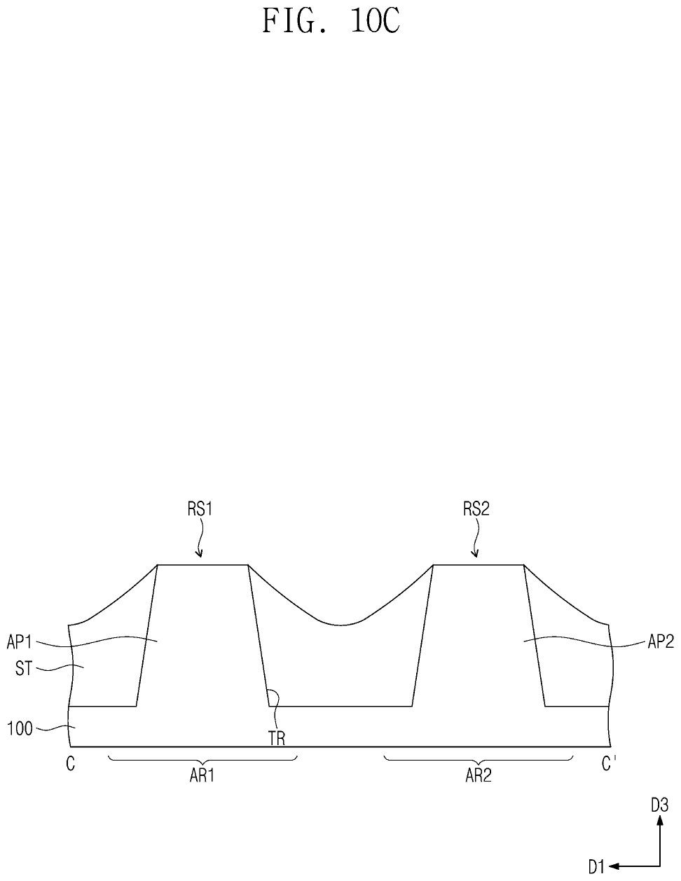

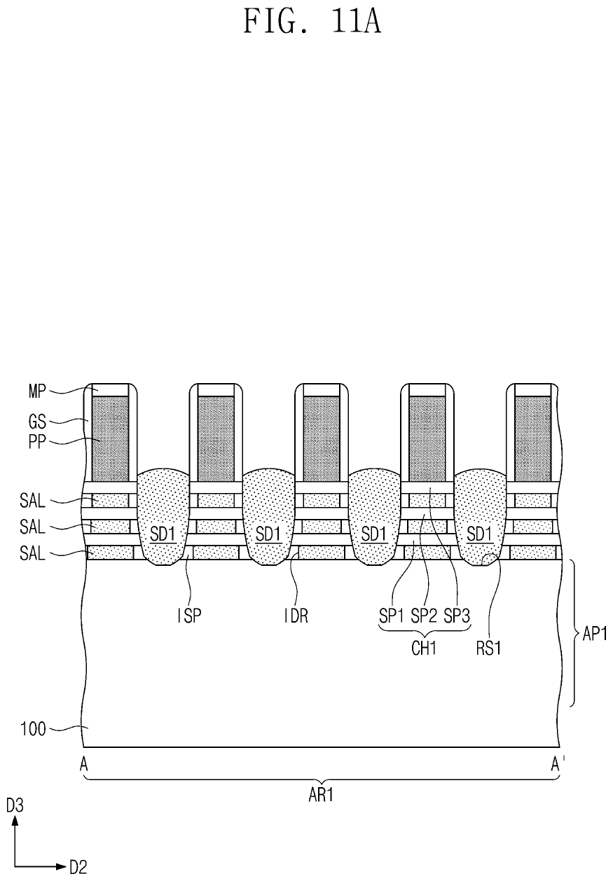

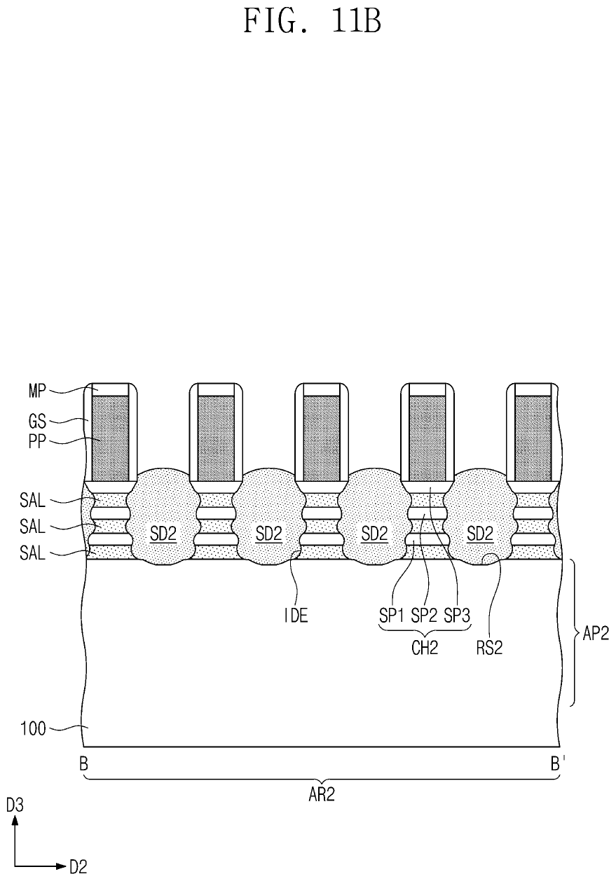

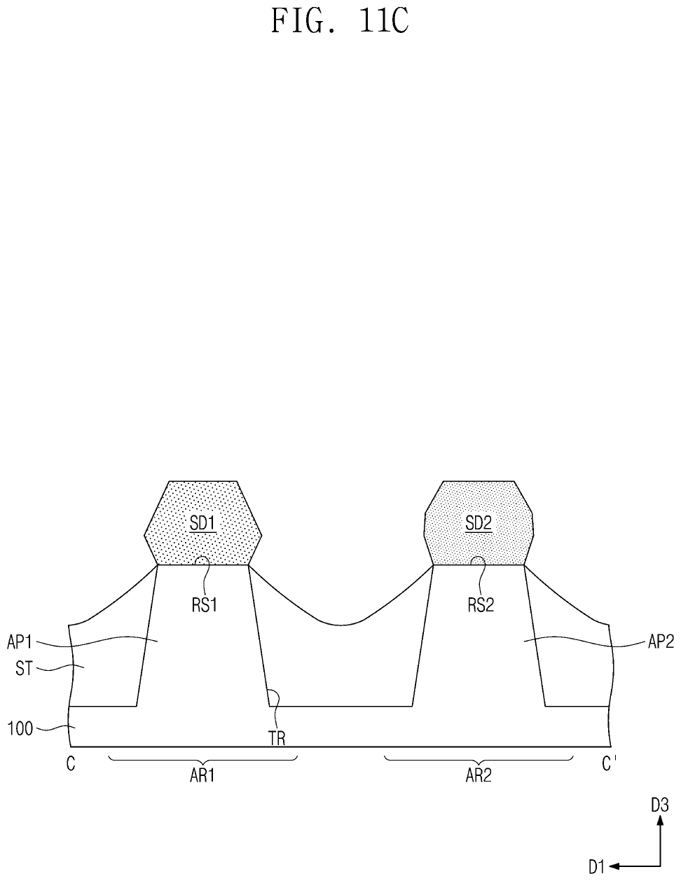

FIGS. 7A to 13C are cross-sectional views illustrating a method of manufacturing a semiconductor device according to some embodiments of the inventive concepts. FIGS. 7A, 8A, 9A, 10A, 11A, 12A and 13A are cross-sectional views corresponding to the line A-A′ of FIG. 4. FIGS. 10B and 11B are cross-sectional views corresponding to the line B-B′ of FIG. 4. FIGS. 10C, 11C, 12B and 13B are cross-sectional views corresponding to the line C-C′ of FIG. 4. FIGS. 7B, 8B, 9B, 12C and 13C are cross-sectional views corresponding to the line D-D′ of FIG. 4.

Referring to FIGS. 7A and 7B, a substrate 100 including first and second active regions AR1 and AR2 is provided. A recess mask pattern RMP may be formed on the substrate 100. The recess mask pattern RMP may have a line shape extending in the second direction D2 and may expose portions in which first curved recesses CRS1 (to be described later) spaced apart from each other in the first direction D1 will be formed. A patterning process may be performed using the recess mask pattern RMP as an etch mask to form the first curved recesses CRS1. The first curved recess CRS1 may have a downward concave shape. The concave shape, for example, may be achieved by controlling an etch depth of the recess. Due to the formation of the first curved recess CRS1, sacrificial layers SAL and active layers ACL may be deposited with the same curvature as the first curved recess CRS1 in a subsequent process.

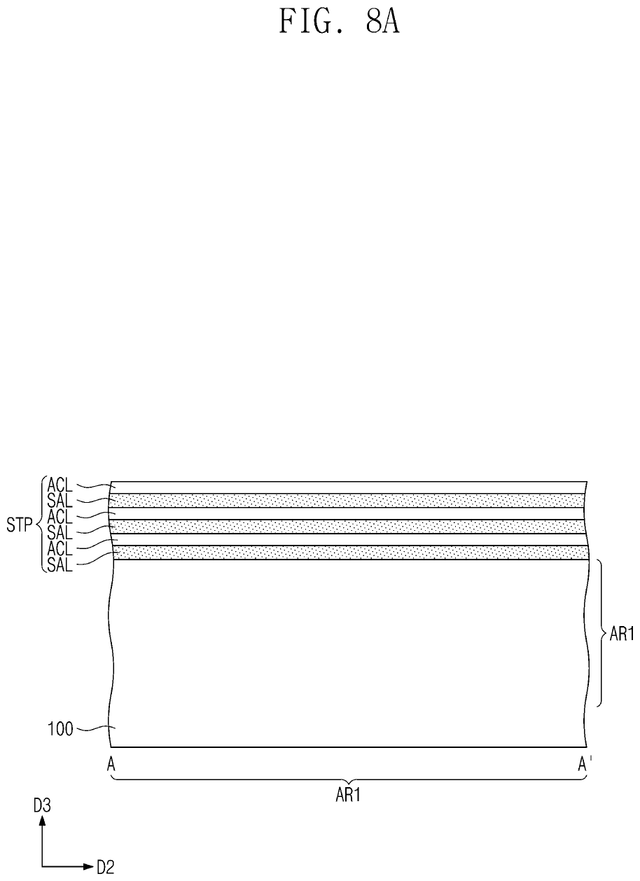

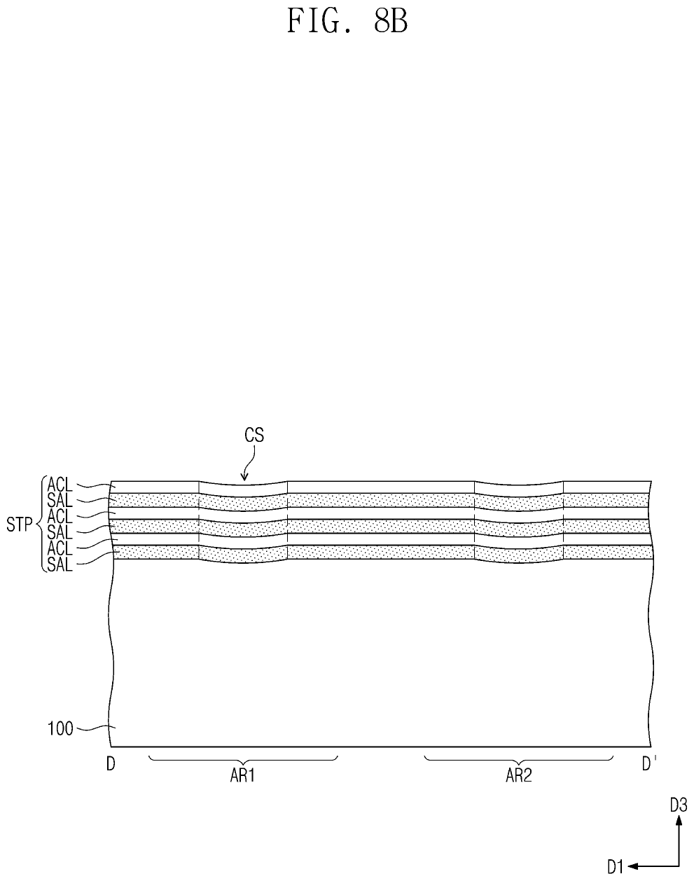

Referring to FIGS. 8A and 8B, the recess mask pattern RMP may be removed after the formation of the first curved surface CRS1. Thereafter, the sacrificial layers SAL and the active layers ACL may be formed to be alternately stacked on the substrate 100. For example, each of the active layers ACL may be formed on each of the sacrificial layers SAL. The active layers ACL may include or be one of silicon (Si), germanium (Ge) and silicon-germanium (SiGe), and the sacrificial layers SAL may include or be another of silicon (Si), germanium (Ge) and silicon-germanium (SiGe). Even though not shown in the drawings, a barrier layer may be additionally deposited between the sacrificial layer SAL and the active layer ACL. The barrier layer (not shown) may include or be silicon (Si) and oxygen (O).

The sacrificial layer SAL may include or be formed of a material having an etch selectivity with respect to the active layer ACL. For example, the active layers ACL may be silicon (Si), and the sacrificial layers SAL may be silicon-germanium (SiGe). A concentration of germanium (Ge) of each of the sacrificial layers SAL may range from 10 at % to 30 at %.

The sacrificial layers SAL and the active layers ACL formed on the first curved recess CRS1 described above may be deposited along a profile of the first curved recess CRS1. In this case, the sacrificial layers SAL and the active layers ACL may be deposited in parallel to a top surface of the substrate 100 on a portion except the first curved recess CRS1. In this case, the sacrificial layers SAL and the active layers ACL on the first curved recess CRS1 may have a certain curvature.

Since the sacrificial layers SAL and the active layers ACL are deposited on each of the first and second active regions AR1 and AR2, a stack pattern STP may be formed. The stack pattern STP may include the sacrificial layers SAL and the active layers ACL, which are alternately stacked.

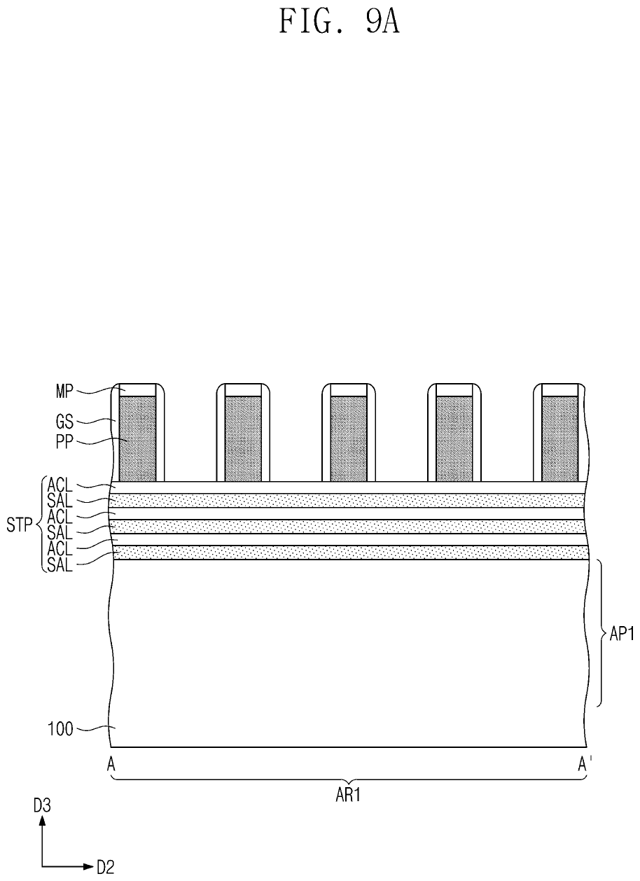

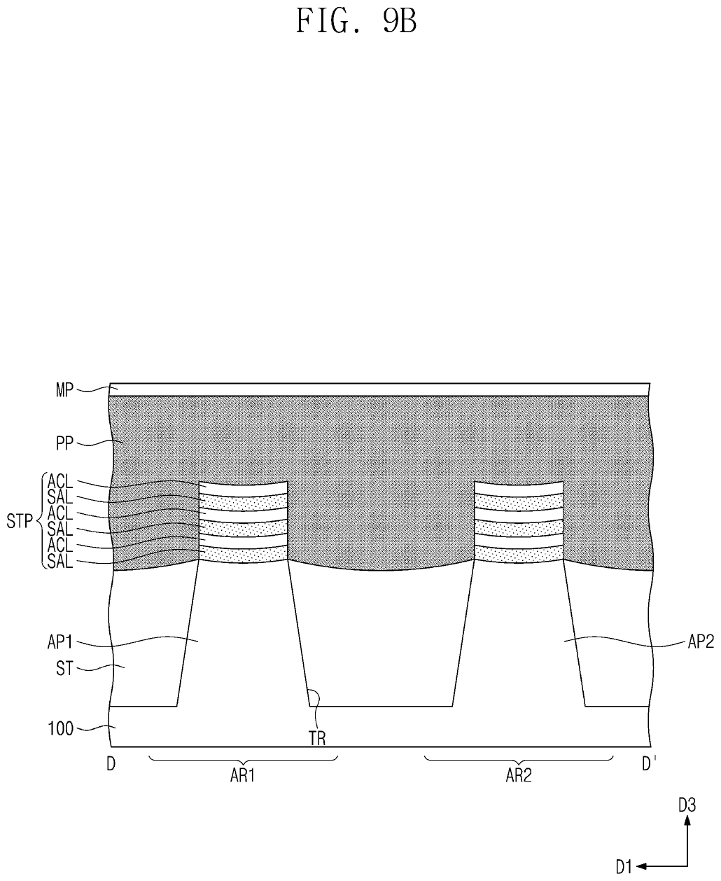

Referring to FIGS. 9A and 9B, mask patterns (not shown) may be formed on the first and second active regions AR1 and AR2 of the substrate 100, respectively. Each of the mask patterns (not shown) may have a line shape or bar shape extending in the second direction D2.

A patterning process may be performed using the mask patterns (not shown) as etch masks to form a trench TR defining a first active pattern AP1 and a second active pattern AP2. The first active pattern AP1 may be formed on the first active region AR1. The second active pattern AP2 may be formed on the second active region AR2.

In an etching process of the patterning process, a portion of the stack pattern STP may be etched to leave stack patterns STP on the first and second active patterns AP1 and AP2.

A device isolation layer ST filling the trench TR may be formed. For example, an insulating layer covering the first and second active patterns AP1 and AP2 and the stack patterns STP may be formed on an entire top surface of the substrate 100. The insulating layer may be recessed until the stack patterns STP are exposed, thereby forming the device isolation layer ST.

The device isolation layer ST may include or be formed of an insulating material (e.g., silicon oxide). The stack patterns STP may be exposed above the device isolation layer ST. In other words, the stack patterns STP may vertically protrude above the device isolation layer ST. In this case, a top surface of the stack pattern STP may include or be a curved surface.

Sacrificial patterns PP intersecting the stack patterns STP may be formed on the substrate 100. Each of the sacrificial patterns PP may be formed to have a line shape or bar shape extending in the first direction D1. The sacrificial patterns PP may be arranged at a first pitch in the second direction D2.

For example, the formation of the sacrificial patterns PP may include forming a sacrificial layer on an entire top surface of the substrate 100, forming hard mask patterns MP on the sacrificial layer, and patterning the sacrificial layer using the hard mask patterns MP as etch masks. The sacrificial layer may include or be poly-silicon.

A pair of gate spacers GS may be formed on both sidewalls of each of the sacrificial patterns PP, respectively. The formation of the gate spacers GS may include conformally forming a gate spacer layer on an entire top surface of the substrate 100 and anisotropically etching the gate spacer layer. In some embodiments, the gate spacer GS may be formed of a multi-layer including at least two layers.

Referring to FIGS. 10A to 10C, first recesses RS1 may be formed in the stack pattern STP on the first active pattern AP1. Second recesses RS2 may be formed in the stack pattern STP on the second active pattern AP2. The device isolation layer ST at both sides of each of the first and second active patterns AP1 and AP2 may further be recessed in the formation of the first and second recesses RS1 and RS2 (see FIG. 10C).

More particularly, the stack pattern STP on the first active pattern AP1 may be etched using the hard mask patterns MP and the gate spacers GS as etch masks to form the first recesses RS1. The first recess RS1 may be formed between a pair of the sacrificial patterns PP.

First to third semiconductor patterns SP1, SP2 and SP3 sequentially stacked between the first recesses RS1 adjacent to each other may be formed from the active layers ACL, respectively. The first to third semiconductor patterns SP1, SP2 and SP3 between the first recesses RS1 adjacent to each other may constitute a first channel pattern CH1.

The first recess RS1 may be formed between the sacrificial patterns PP adjacent to each other. A width of the first recess RS1 in the second direction D2 may become progressively less toward the substrate 100.

The sacrificial layers SAL may be exposed by the first recess RS1. A selective etching process may be performed on the exposed sacrificial layers SAL. The etching process may include a wet etching process of selectively removing silicon-germanium. Each of the sacrificial layers SAL may be indented by the etching process to form an indent region IDR. A sidewall of the sacrificial layer SAL may be concave by the indent region IDR. An insulating layer filling the indent regions IDR may be formed in the first recess RS1. The first to third semiconductor patterns SP1, SP2 and SP3 and the sacrificial layers SAL exposed by the first recess RS1 may be used as a seed layer of the insulating layer. The insulating layer may be a crystalline dielectric layer grown on the crystalline semiconductor material of the first to third semiconductor patterns SP1, SP2 and SP3 and the sacrificial layers SAL.

An inner spacer ISP filling the indent region IDR may be formed. For example, the formation of the inner spacer ISP may include performing a wet etching process on the insulating layer (e.g., an epitaxial dielectric layer) to expose sidewalls of the first to third semiconductor patterns SP1, SP2 and SP3. Thus, the epitaxial dielectric layer may remain in only the indent region IDR to form the inner spacer ISP.

Referring again to FIGS. 10A to 10C, the second recesses RS2 in the stack pattern STP on the second active pattern AP2 may be formed by a method similar to the method of forming the first recesses RS1. A selective etching process may be performed on the sacrificial layers SAL exposed by the second recess RS2, and thus indent regions IDE may be formed on the second active pattern AP2. The second recess RS2 may have a wave-shaped inner sidewall by the indent regions IDE. The inner spacers ISP may not be formed in the indent regions IDE on the second active pattern AP2. The first to third semiconductor patterns SP1, SP2 and SP3 between the second recesses RS2 adjacent to each other may constitute a second channel pattern CH2.

Referring to FIGS. 11A to 11C, first source/drain patterns SD1 may be formed in the first recesses RS1, respectively. For example, a SEG process may be performed using an inner surface of the first recess RS1 as a seed layer to form an epitaxial layer filling the first recess RS1. The epitaxial layer may be grown using the first to third semiconductor patterns SP1, SP2 and SP3 and the substrate 100, exposed by the first recess RS1, as a seed. For example, the SEG process may include a chemical vapor deposition (CVD) process or a molecular beam epitaxy (MBE) process.

In some embodiments, the first source/drain pattern SD1 may include or be formed of the same semiconductor element (e.g., Si) as the substrate 100. Dopants (e.g., phosphorus, arsenic or antimony) for allowing the first source/drain pattern SD1 to have an n-type may be injected in-situ during the formation of the first source/drain pattern SD1. Alternatively, after the formation of the first source/drain pattern SD1, the dopants may be injected or implanted into the first source/drain pattern SD1.

Second source/drain patterns SD2 may be formed in the second recesses RS2, respectively. For example, the second source/drain pattern SD2 may be formed by performing a SEG process using an inner surface of the second recess RS2 as a seed layer.

In some embodiments, the second source/drain pattern SD2 may include or be formed of a semiconductor element (e.g., SiGe) having a lattice constant greater than a lattice constant of the semiconductor element of the substrate 100. Dopants (e.g., boron, gallium or indium) for allowing the second source/drain pattern SD2 to have a p-type may be injected in-situ during the formation of the second source/drain pattern SD2. Alternatively, after the formation of the second source/drain pattern SD2, the dopants may be injected or implanted into the second source/drain pattern SD2.

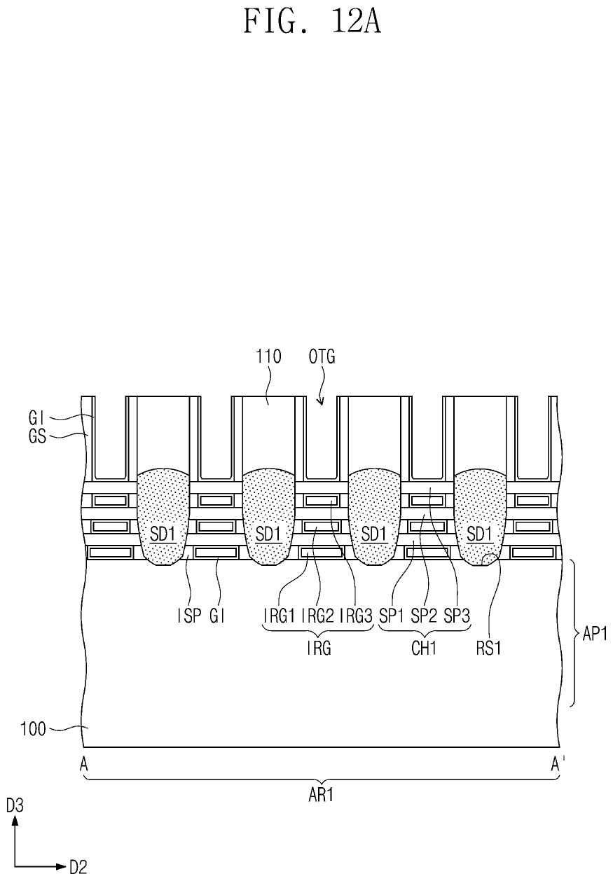

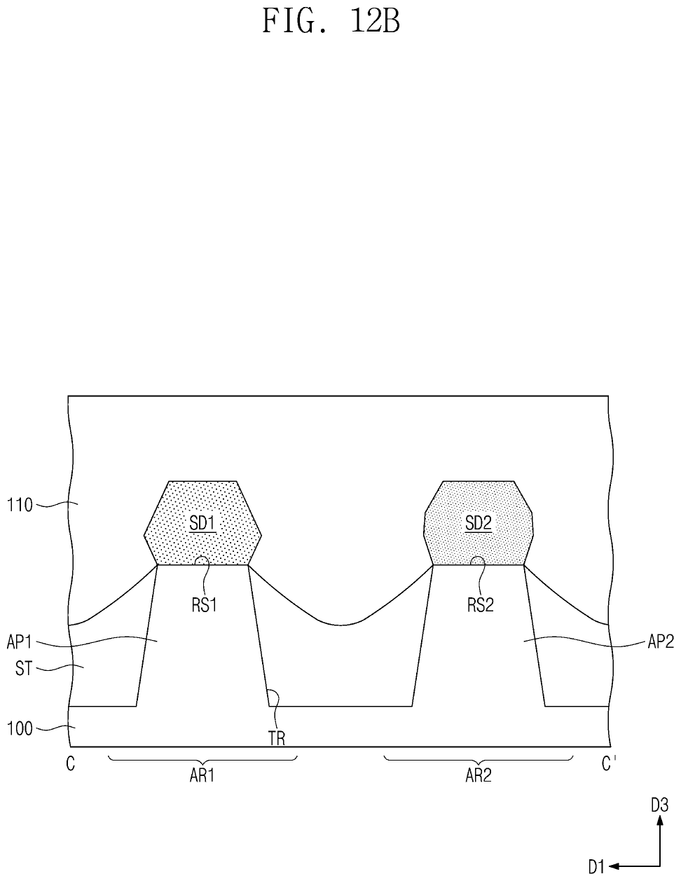

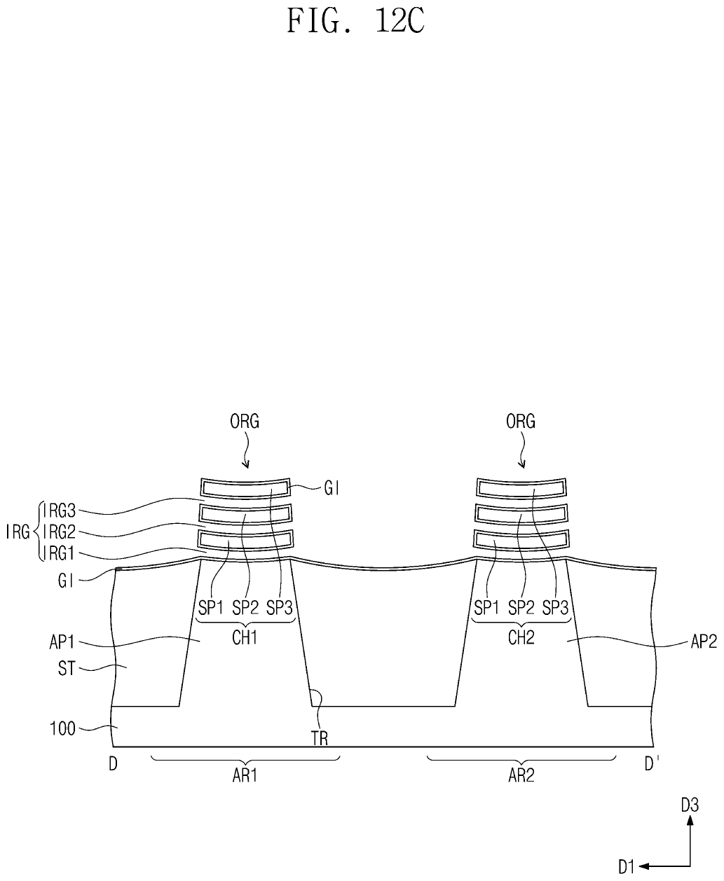

Referring to FIGS. 12A to 12C, a first interlayer insulating layer 110 may be formed to cover the first and second source/drain patterns SD1 and SD2, the hard mask patterns MP and the gate spacers GS. For example, the first interlayer insulating layer 110 may be or include a silicon oxide layer.

The first interlayer insulating layer 110 may be planarized to expose top surfaces of the sacrificial patterns PP. The planarization of the first interlayer insulating layer 110 may be performed using an etch-back process or a chemical mechanical polishing (CMP) process. The hard mask patterns MP may be completely removed during the planarization process. As a result, a top surface of the first interlayer insulating layer 110 may be substantially coplanar with the top surfaces of the sacrificial patterns PP and top surfaces of the gate spacers GS.

The exposed sacrificial patterns PP may be selectively removed. An outer region ORG exposing the first and second channel patterns CH1 and CH2 may be formed by the removal of the sacrificial pattern PP (see FIG. 12C). The removal of the sacrificial patterns PP may include performing a wet etching process using an etching solution capable of selectively etching poly-silicon.

The sacrificial layers SAL exposed through the outer region ORG may be selectively removed to form inner regions IRG (see FIG. 12C). For example, an etching process of selectively etching the sacrificial layers SAL may be performed to remove the sacrificial layers SAL while leaving the first to third semiconductor patterns SP1, SP2 and SP3. Top surfaces of the first to third semiconductor patterns SP1, SP2 and SP3 may be curved. The etching process may have a high etch rate with respect to silicon-germanium having a relatively high germanium concentration. For example, the etching process may have a high etch rate with respect to silicon-germanium having a germanium concentration greater than 10 at %.

A time of the process of removing the sacrificial layer SAL may be reduced to prevent a phenomenon in which the source/drain patterns SD1 and SD2 are etched. Therefore, a short phenomenon between a gate and a source/drain (e.g., PC to eSiGe short) may be prevented to improve electrical characteristics. In addition, etch selectivity may be improved to reduce or minimize the amount of the sacrificial layer SAL remaining on a surface of the barrier layer (not shown) after the etching process. Thus, a gate insulating layer and a high-k dielectric layer may be uniformly formed in a process of forming a gate electrode. As a result, reliability and electrical characteristics of the semiconductor device according to the inventive concepts may be improved.

The sacrificial layers SAL on the first and second active regions AR1 and AR2 may be removed during the etching process. The etching process may be a wet etching process. An etching material used in the etching process may quickly remove the sacrificial layer SAL having a relatively high germanium concentration.

Referring again to FIG. 12C, since the sacrificial layers SAL are selectively removed, the stacked first to third semiconductor patterns SP1, SP2 and SP3 may remain on each of the first and second active patterns AP1 and AP2. First to third inner regions IRG1, IRG2 and IRG3 may be formed by the removal of the sacrificial layers SAL.

In detail, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring again to FIGS. 12A to 12C, a gate insulating layer GI is formed on the exposed first to third semiconductor patterns SP1, SP2 and SP3. The gate insulating layer GI may be formed to surround each of the first to third semiconductor patterns SP1, SP2 and SP3. The gate insulating layer GI may be formed in each of the first to third inner regions IRG1, IRG2 and IRG3. The gate insulating layer GI may be formed in the outer region ORG. The gate insulating layer GI may be formed on the first and second active patterns AP1 and AP2 and the device isolation layer ST.

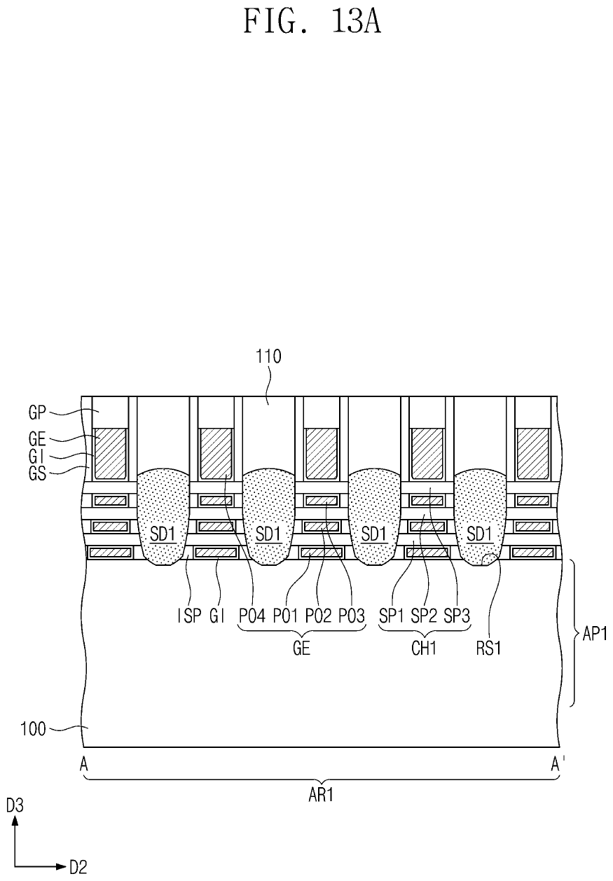

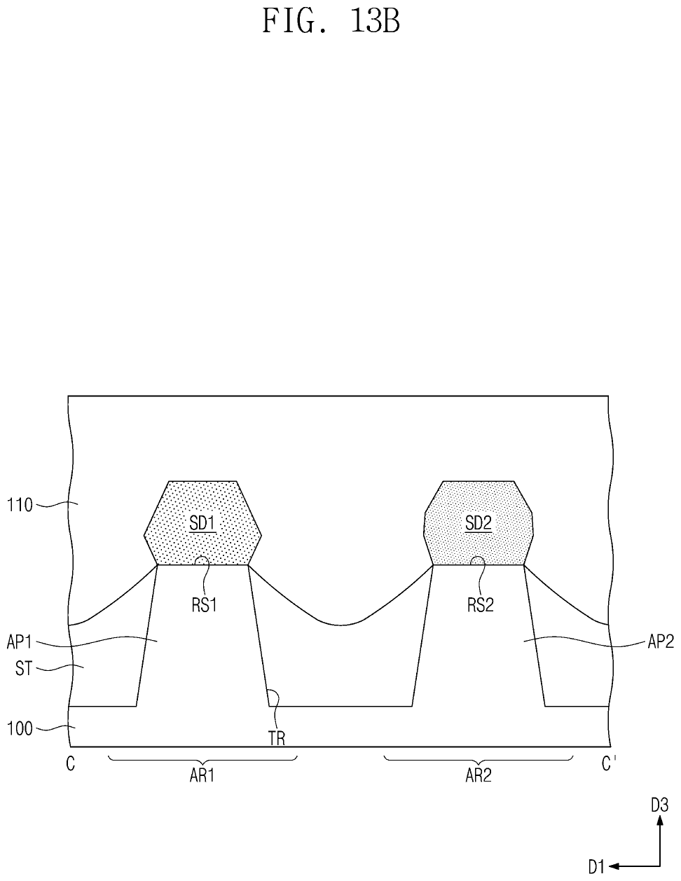

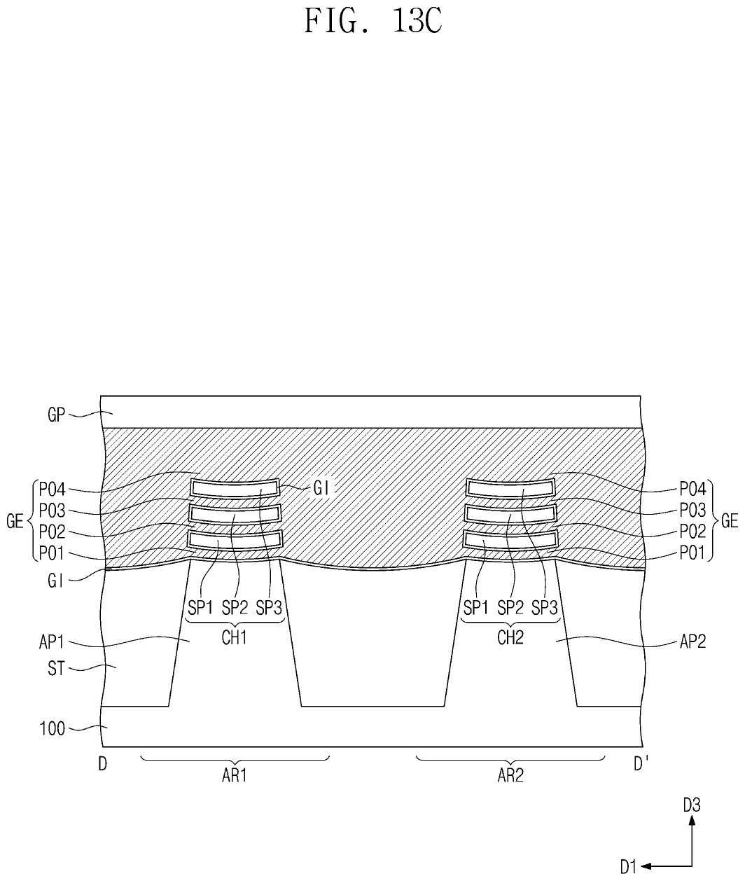

Referring to FIGS. 13A to 13C, a gate electrode GE is formed on the gate insulating layer GI. The gate electrode GE may include first to third portions PO1, PO2 and PO3 formed in the first to third inner regions IRG1, IRG2 and IRG3, respectively, and a fourth portion PO4 formed in the outer region ORG. The gate electrode GE may be recessed to reduce its height. A gate capping pattern GP may be formed on the recessed gate electrode GE.

Referring again to FIGS. 5A to 5D, a second interlayer insulating layer 120 may be formed on the first interlayer insulating layer 110. The second interlayer insulating layer 120 may include or be a silicon oxide layer. Active contacts AC may be formed to penetrate the second interlayer insulating layer 120 and the first interlayer insulating layer 110, and the active contacts AC may be electrically connected to the first and second source/drain patterns SD1 and SD2. A gate contact GC may be formed to penetrate the second interlayer insulating layer 120 and the gate capping pattern GP, and the gate contact GC may be electrically connected to the gate electrode GE.

The formation of each of the active contact AC and the gate contact GC may include forming a barrier pattern BM, and forming a conductive pattern FM on the barrier pattern BM. The barrier pattern BM may be conformally formed and may include a metal layer/a metal nitride layer. The conductive pattern FM may include a low-resistance metal.

Isolation structures DB may be formed at a first boundary BD1 and a second boundary BD2 of the single height cell SHC, respectively. The isolation structure DB may penetrate the second interlayer insulating layer 120 and the gate electrode GE and may extend into the active pattern AP1 or AP2. The isolation structure DB may include an insulating material such as silicon oxide or silicon nitride.

A third interlayer insulating layer 130 may be formed on the active contacts AC and the gate contacts GC. A first metal layer M1 may be formed in the third interlayer insulating layer 130. A fourth interlayer insulating layer 140 may be formed on the third interlayer insulating layer 130. A second metal layer M2 may be formed in the fourth interlayer insulating layer 140.

In the semiconductor device according to aspects of the inventive concepts, since the top surfaces of the semiconductor patterns are curved, the lengths of the top surfaces may be greater than the straight widths of the semiconductor patterns, respectively, and thus surface areas of the semiconductor patterns in contact with the gate electrode may be increased as compared with a case in which top surfaces of semiconductor patterns are not curved. As a result, the amount of a flowing current per unit area of the semiconductor pattern may be more increased to improve electrical characteristics of the semiconductor device.

While the embodiments of the inventive concepts have been particularly shown and described, it will be understood by one of ordinary skill in the art that variations in form and detail may be made therein without departing from the spirit and scope of the attached claims.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.).

What is claimed is:

1. A semiconductor device comprising:
a substrate including an active pattern;
a first semiconductor pattern on the active pattern;
a source/drain pattern connected to the first semiconductor pattern; and
gate electrodes extending in a first direction and arranged in a second direction intersecting the first direction,
wherein a first top surface of the first semiconductor pattern ends at a first corner and a second corner, which are spaced apart from each other in the first direction,
wherein the first top surface of the first semiconductor pattern includes a first portion connecting the first corner and the second corner, and
wherein a length of the first portion of the first semiconductor pattern along a direction parallel to the first direction when viewed from a plan view is greater than a distance in the first direction between the first corner and the second corner.

2. The semiconductor device of claim 1, wherein the first corner and second corner correspond to a respective first edge and second edge of the first top surface of the first semiconductor pattern.

3. The semiconductor device of claim 1, further comprising:
a second semiconductor pattern overlapping with the first semiconductor pattern in a third direction intersecting the first direction and the second direction,
wherein a second top surface of the second semiconductor pattern ends at a third corner and a fourth corner, which are spaced apart from each other in the first direction,
wherein the second top surface of the second semiconductor pattern includes a second portion connecting the third corner and the fourth corner, and
wherein the length of the first portion along the direction parallel to the first direction when viewed from the plan view is greater than a length of the second portion along the direction parallel to the first direction when viewed from the plan view.

4. The semiconductor device of claim 3, wherein the length of the first portion along the direction parallel to the first direction when viewed from the plan view is in a range from 1.02 times to 1.05 times the length of the second portion along the direction parallel to the first direction when viewed from the plan view.

5. The semiconductor device of claim 3, wherein the length of the first portion along the direction parallel to the first direction when viewed from the plan view is in a range from 1.2 times to 1.4 times the distance in the first direction between the first corner and the second corner.

6. The semiconductor device of claim 3, wherein a first bottom surface of the first semiconductor pattern includes a first lower corner and a second lower corner, which are spaced apart from each other in the first direction,
wherein the first bottom surface of the first semiconductor pattern includes a first lower portion connecting the first lower corner and the second lower corner, and
wherein the length of the first portion along the direction parallel to the first direction when viewed from the plan view is less than a length of the first lower portion along the direction parallel to the first direction when viewed from the plan view.

7. The semiconductor device of claim 1, wherein a top surface of the active pattern, which overlaps the first semiconductor pattern, includes a first active corner and a second active corner which are spaced apart from each other in the first direction, and
wherein the top surface of the active pattern includes an active curved portion connecting the first active corner and the second active corner.

8. The semiconductor device of claim 7, wherein a curvature of the active curved portion is equal to a curvature of the first portion.

9. The semiconductor device of claim 1, further comprising:
a gate insulating layer surrounding the first semiconductor pattern,
wherein a top surface of the gate insulating layer includes a curved surface.

10. A semiconductor device comprising:
a substrate including an active pattern;
a first semiconductor pattern on the active pattern;
a source/drain pattern connected to the first semiconductor pattern; and
gate electrodes extending in a first direction and arranged in a second direction intersecting the first direction,
wherein a top surface of the active pattern includes a curved surface.

11. The semiconductor device of claim 10, further comprising:
a second semiconductor pattern overlapping with the first semiconductor pattern in a third direction intersecting the first direction and the second direction,
wherein a first top surface of the first semiconductor pattern includes a first edge and a second edge, which are spaced apart from each other in the first direction,
wherein the first top surface of the first semiconductor pattern includes a first portion connecting the first edge and the second edge,
wherein a second top surface of the second semiconductor pattern includes a third edge and a fourth edge, which are spaced apart from each other in the first direction, and
wherein the second top surface of the second semiconductor pattern includes a second portion connecting the third edge and the fourth edge.

12. The semiconductor device of claim 11, wherein a curvature of the first portion is equal to a curvature of the second portion.

13. The semiconductor device of claim 11, wherein the active pattern includes an active curved portion overlapping with the first portion.

14. The semiconductor device of claim 13, wherein a curvature of the active curved portion is equal to a curvature of the first portion of the first semiconductor pattern.

15. The semiconductor device of claim 11, wherein a length of the first portion is greater than a length of the second portion.

16. The semiconductor device of claim 11, wherein a distance in the first direction between the first edge and the second edge of the first semiconductor pattern is greater than a distance in the first direction between the third edge and the fourth edge of the second semiconductor pattern.

17. The semiconductor device of claim 11, further comprising:
a gate insulating layer between a first gate electrode of the gate electrodes and the first and second semiconductor patterns,
wherein a top surface of the gate insulating layer includes a curved surface, and
wherein a curvature of the curved surface of the top surface of the gate insulating layer is equal to a curvature of the first portion.

18. A semiconductor device comprising:
a substrate including an active region;
a device isolation layer defining an active pattern on the active region;
a first semiconductor pattern and a second semiconductor pattern sequentially stacked on the active pattern, the first and second semiconductor patterns vertically spaced apart from each other;
a source/drain pattern connected to the first and second semiconductor patterns;
gate electrodes extending in a first direction and arranged in a second direction intersecting the first direction;
a gate capping pattern on a top surface of each gate electrode;
an interlayer insulating layer on each gate capping pattern;
an active contact penetrating the interlayer insulating layer so as to be electrically connected to the source/drain pattern;
respective gate contacts penetrating the interlayer insulating layer and the gate capping pattern so as to be electrically connected to a respective gate electrode;
a first metal layer including a power interconnection line and first interconnection lines on the interlayer insulating layer, the active contact electrically connected to a corresponding one of the power and first interconnection lines, and a gate contact electrically connected to a corresponding one of the power and first interconnection lines; and
a second metal layer on the first metal layer,
wherein the second metal layer includes second interconnection lines electrically connected to the first metal layer,
wherein a first top surface of the first semiconductor pattern includes a first edge and a second edge, which are spaced apart from each other in the first direction,
wherein the first top surface of the first semiconductor pattern includes a first portion connecting the first edge and the second edge,
wherein a second top surface of the second semiconductor pattern includes a third edge and a fourth edge, which are spaced apart from each other in the first direction,
wherein the second top surface of the second semiconductor pattern includes a second portion connecting the third edge and the fourth edge, and
wherein a length of the first portion of the first semiconductor pattern along a direction parallel to the first direction when viewed from a plan view is greater than a distance in the first direction between the first edge and the second edge.

19. The semiconductor device of claim 18, wherein a curvature of the first portion is equal to a curvature of the second portion.

20. The semiconductor device of claim 18, wherein the active pattern includes an active curved surface overlapping with the first top surface,
wherein the active curved surface includes an active curved portion overlapping with the first portion, and
wherein a curvature of the active curved portion is equal to a curvature of the first portion.
